(19) United States
(12) Patent Application Publication
(10) Pub. No.: US 2025/0040277 A1
(43) Pub. Date: Jan. 30, 2025

(54) IMAGE SENSOR

(71) Applicant: Samsung Electronics Co., Ltd., Suwon-si (KR)

(72) Inventor: Juntaek LEE, Suwon-si (KR)

(73) Assignee: Samsung Electronics Co., Ltd., Suwon-si (KR)

(21) Appl. No.: 18/436,267

(22) Filed: Feb. 8, 2024

(30) Foreign Application Priority Data
Jul. 27, 2023 (KR) 10-2023-0098526

(51) Int. Cl. H01L 27/146

(52) U.S. Cl. CPC H01L 27/14621; H01L 27/14627; H01L 27/1463; H01L 27/14643; H01L 27/14685

(57) ABSTRACT

An image sensor includes a plurality of pixels arranged in a matrix form, photodiodes for the respective pixels, the photodiodes within a semiconductor substrate having a first surface to which light is incident and a second surface that faces away from the first surface, micro lenses over the first surface of the semiconductor substrate and configured to concentrate the light, color filters between the semiconductor substrate and the micro lenses, and an optical path changing member configured to change a path of at least a portion of the light when the light travels toward the photodiodes through the micro lenses. The optical path changing member having a curved surface being concave or convex on the first surface of the semiconductor substrate.

### CROSS-REFERENCE TO RELATED APPLICATION

This application claims priority under 35 U.S.C. § 119 to Korean Patent Application No. 10-2023-0098526 filed on Jul. 27, 2023, in the Korean Intellectual Property Office, the disclosures of which are incorporated by reference herein in their entireties.

### BACKGROUND

Example embodiments of the present inventive concepts described herein relate to image sensors.

Image sensors are devices that convert an optical image into an electrical signal. The image sensors may be classified into a charge coupled device (CCD) image sensor and a complementary metal oxide semiconductor (CMOS) image sensor. The CMOS image sensor is abbreviated as CIS. The CIS includes a plurality of pixels arranged in two dimensions.

Each of the pixels includes a photodiode (PD) formed within a semiconductor substrate and a micro lens provided on the semiconductor substrate. The photodiode serves to convert incident light into an electrical signal, and the micro lens serves to concentrate light incident toward the photodiode.

However, when the light concentrated by the micro lens does not travel toward the photodiode, the light receiving efficiency of the photodiode is decreased. Accordingly, improvements are advantageous to provide in this regard.

### SUMMARY

Example embodiments of the present inventive concepts provide image sensors with improved light receiving efficiency. Example embodiments of the present inventive concepts provide image sensors for improving crosstalk phenomenon caused by plain light.

According to some example embodiments, an image sensor includes a plurality of pixels arranged in a matrix form, photodiodes for respective pixels of the plurality of pixels, the photodiodes within a semiconductor substrate having a first surface to which light is incident and a second surface facing away from the first surface, micro lenses over the first surface of the semiconductor substrate and configured to concentrate the light, color filters between the semiconductor substrate and the micro lenses, and an optical path changing member configured to change a path of at least a portion of the light when the light travels toward the photodiodes through the micro lenses, wherein the optical path changing member has a curved surface being concave or convex on the first surface of the semiconductor substrate.

In some example embodiments, at least two pixels among the plurality of pixels share one micro lens among the micro lenses, and the optical path changing member, when viewed from above a plane, is at a center of the at least two pixels.

In some example embodiments, the optical path changing member has the curved surface being concave or convex in a direction from the first surface of the semiconductor substrate toward the second surface of the semiconductor substrate.

According to some example embodiments, an image sensor includes a plurality of pixel groups, each of which has one color among first to third colors, wherein each of the plurality of pixel groups includes first to fourth pixels arranged in a 2×2 matrix form, photodiodes for the first to fourth pixels, the photodiodes within a semiconductor substrate having a first surface to which light is incident and a second surface facing away from the first surface, micro lenses over the first surface of the semiconductor substrate corresponding to the first to fourth pixels and configured to concentrate the light, a color filter between the semiconductor substrate and the micro lenses, and an optical path changing member configured to change a path of at least a portion of the light when the light travels toward the photodiodes through the micro lenses, wherein the optical path changing member has a curved surface extending from the first surface of the semiconductor substrate, the curved surface being concave or convex in a direction toward the second surface of the semiconductor substrate.

According to some example embodiments, a method for manufacturing an image sensor includes providing a semiconductor substrate having a first surface and a second surface facing away from the first surface, the semiconductor substrate including photodiodes and pixel isolators formed therein, forming an optical path changing member on a region of the first surface of the semiconductor substrate configured to overlap the pixel isolators when viewed from above a plane, forming a color filter on the semiconductor substrate having the optical path changing member formed thereon, and forming a micro lens on the semiconductor substrate having the color filter formed thereon, wherein the optical path changing member has a curved surface extending from the first surface of the semiconductor substrate, the curved surface being concave or convex in a direction toward the second surface of the semiconductor substrate.

### BRIEF DESCRIPTION OF THE DRAWINGS

The above and other objects and features of the present inventive concepts will become apparent by describing in detail example embodiments thereof with reference to the accompanying drawings.

FIG. 1 is a block diagram of an image sensor according to some example embodiments.

FIG. 2 illustrates a pixel array including a plurality of pixel groups in the image sensor according to some example embodiments.

FIG. 3 is a view illustrating a circuit diagram of a pixel according to some example embodiments.

FIG. 4A is a plan view illustrating portion P1 in FIG. 2 according to some example embodiments,

FIG. 4B is a plan view illustrating a second pixel group in FIG. 4A according to some example embodiments.

FIGS. 5A and 5B are sectional views taken along line A-A′ and line B-B′ of FIG. 4B according to some example embodiments.

FIG. 6 illustrates an image sensor according to some example embodiments, where FIG. 6 is a plan view corresponding to the second pixel group PXG2 of FIG. 4A.

FIG. 7 is a sectional view taken along line A-A′ of FIG. 6 according to some example embodiments.

FIGS. 8, 9, 10, and 11 illustrate image sensors according some example embodiments, where FIGS. 8 to 11 are sectional views corresponding to line A-A′ of FIG. 4A.

FIG. 12A illustrates an image sensor according to some example embodiments, where FIG. 12A is a plan view corresponding to the second pixel group of FIG. 4A.

FIG. 12B is a sectional view taken along line A-A′ of FIG. 12A according to some example embodiments.

FIG. 13 illustrates an image sensor according to some example embodiments, where FIG. 13 is a sectional view taken along line A-A′ in a plan view corresponding to the second pixel group of FIG. 4A.

FIGS. 14A and 14B are plan views corresponding to the second pixel group of FIG. 4A in an image sensor according to some example embodiments.

FIGS. 15A to 15F are sectional views sequentially illustrating a method for manufacturing the image sensor illustrated in FIG. 5A according to some example embodiments.

FIGS. 16A to 16C are sectional views sequentially illustrating a method for manufacturing the image sensor illustrated in FIG. 8 according to some example embodiments.

FIGS. 17A to 17C are sectional views sequentially illustrating a method for manufacturing the image sensor illustrated in FIG. 9 according to some example embodiments, where processes substantially the same as those in the above-described embodiments are omitted.

FIGS. 18A to 18G are sectional views sequentially illustrating a method for manufacturing the image sensor illustrated in FIG. 10 according to some example embodiments.

FIG. 19 is a view illustrating a pixel array including a plurality of pixel groups according to some example embodiments.

FIG. 20 is a plan view illustrating portion P2 in FIG. 19 according to some example embodiments.

FIG. 21 is a sectional view taken along line A-A′ of FIG. 20 according to some example embodiments.

FIGS. 22, 23, 24, and 25 illustrate image sensors according to some example embodiments, where FIGS. 22 to 25 are sectional views corresponding to line A-A′ of FIG. 20.

FIG. 26A illustrates a pixel array according to some example embodiments, and FIG. 26B is a plan view illustrating portion P3 in FIG. 26A.

FIG. 27A illustrates a pixel array according to some example embodiments, and FIG. 27B is a plan view illustrating portion P4 in FIG. 27A.

FIG. 28 illustrates a pixel array according to some example embodiments.

### DETAILED DESCRIPTION

Various changes can be made to the present inventive concepts, and various example embodiments of the present inventive concepts may be implemented. Thus, example embodiments are illustrated in the drawings and described as examples herein. However, it should be understood that the present inventive concepts are not to be construed as being limited thereto and covers all modifications, equivalents, and alternatives falling within the spirit and scope of the present inventive concepts.

Hereinafter, some example embodiments of the present inventive concepts will be described in more detail with reference to the accompanying drawings.

The present inventive concepts relate to image sensors including a pixel array including a plurality of pixels. Hereinafter, various example embodiments will be described. The image sensors of the present inventive concepts include photodiodes that receive light having various wavelengths and convert the light into electrical signals. In some example embodiments, the image sensor corresponds to an image sensor that increases light efficiency and reduces crosstalk. Here, the light having various wavelengths refers to light in the visible wavelength band. However, example embodiments are not limited thereto, the light may be light in a wavelength band other than the visible wavelength band, for example, light in the infrared wavelength band or the ultraviolet wavelength band. An image sensor according to some example embodiments may detect, for example, various colors of light, including blue light, green light, and red light in the visible wavelength band. To this end, the image sensor according to some example embodiments may include photodiodes formed within a semiconductor substrate, to which light is incident, to correspond to respective pixels. In some example embodiments, micro lenses are provided adjacent to a light incident surface to concentrate light incident toward the photodiodes. According to some example embodiments, a structure for evenly distributing the light concentrated by the micro lenses to the corresponding pixels is provided.

Hereinafter, an image sensor according to some example embodiments will be described. It will be understood that when an element such as a layer, film, region, or substrate is referred to as being “on” another element, it may be directly on the other element or intervening elements may also be present. In contrast when an element is referred to as being “directly on” another element, there are no intervening elements present. It will further be understood that when an element is referred to as being “on” another element, it may be above or beneath or adjacent (e.g., horizontally adjacent) to the other element. First, a block diagram of the image sensor according to some example embodiments and a corresponding circuit diagram according to some example embodiments will be described, and then specific configurations according to some example embodiments will be described.

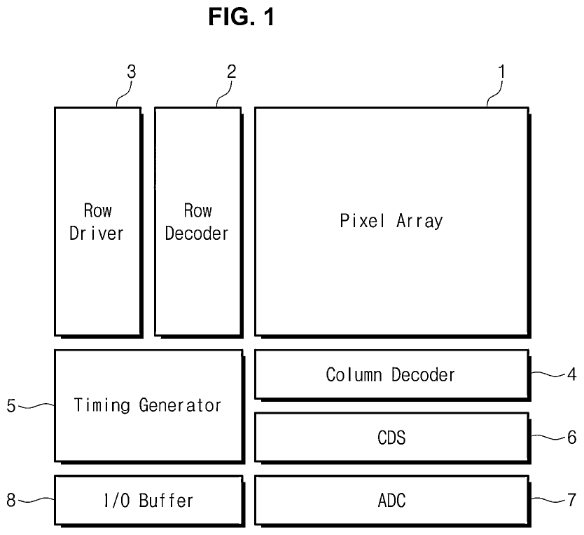

FIG. 1 is the block diagram of the image sensor according to some example embodiments.

Referring to FIG. 1, the image sensor according to some example embodiments includes a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 includes a plurality of pixels arranged in two dimensions and converts an optical signal into an electrical signal. The pixel array 1 may be driven by a plurality of drive signals such as a pixel selection signal, a reset signal, and a charge transmission signal from the row driver 3. In some example embodiments, the converted electrical signal is provided to the correlated double sampler 6.

The row driver 3 provides the plurality of drive signals for driving the plurality of pixels to the pixel array 1 depending on results decoded by the row decoder 2. In some example embodiments, when the pixels are arranged in a matrix form, the drive signals may be provided for respective rows.

The timing generator 5 provides a timing signal and a control signal to the row decoder 2 and the column decoder 4.

The correlated double sampler (CDS) 6 receives, holds, and samples the electrical signal generated by the pixel array 1. The correlated double sampler (CDS) 6 doubly samples a specific noise level and a signal level by the electrical signal and outputs a difference level corresponding to a difference between the noise level and the signal level.

The analog-to-digital converter 7 converts an analog signal corresponding to the difference level output from the correlated double sampler 6 into a digital signal and outputs the digital signal.

The input/output buffer 8 latches the digital signal. The input/output buffer 8 outputs the latched signal to an image signal processor (not illustrated) as a digital signal.

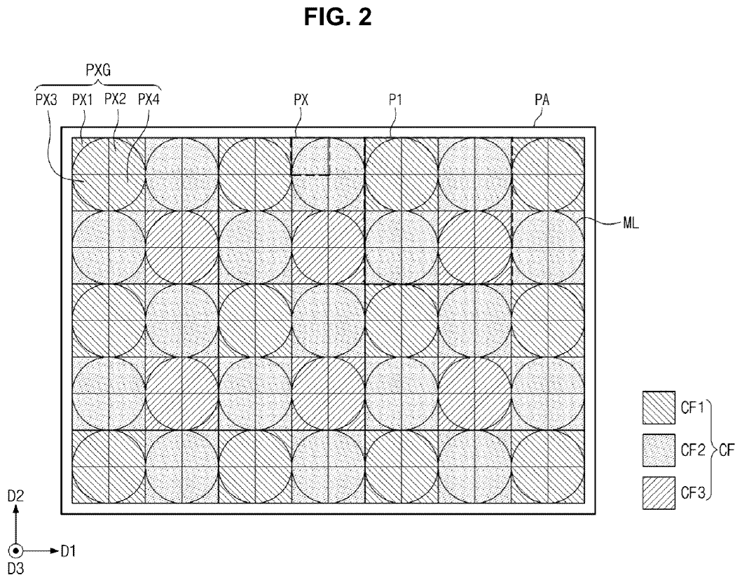

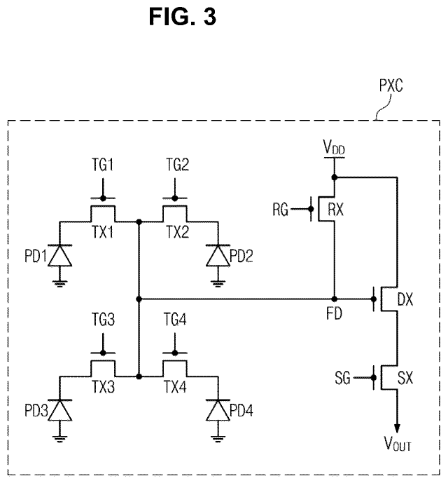

FIG. 2 illustrates a pixel array including a plurality of pixel groups in the image sensor according to some example embodiments, and FIG. 3 is a view illustrating a circuit diagram of a pixel according to some example embodiments. In FIG. 3, pixels have substantially the same configuration and operation in terms of circuitry, and therefore for convenience of description, one pixel will be described.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., +10%) around the stated elements and/or properties thereof.

Referring to FIG. 2, in some example embodiments, the pixel array includes a plurality of pixel groups PXG.

Each of the pixel groups PXG may include first to fourth pixels PX1, PX2, PX3, and PX4 arranged in a 2×2 matrix form. In some example embodiments, a row direction may be a first direction D1, and a column direction may be a second direction D2. The pixel group PXG may include the fourth pixels PX. According to some example embodiments, the plurality of pixel groups PXG may be arranged in a matrix form to form the image sensor.

The pixel groups PXG may be arranged in a matrix form in the first direction D1 and the second direction D2 crossing each other. In some example embodiments, a direction perpendicular to the first direction D1 and the second direction D2 is a third direction D3.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Each of the pixel groups PXG may include the first to fourth pixels PX1, PX2, PX3, and PX4 arranged in a 2×2 matrix form. In some example embodiments, the row direction may be the first direction D1, and the column direction may be the second direction D2. The first and second pixels PX1 and PX2 are sequentially disposed in the first direction D1, and the third and fourth pixels PX3 and PX4 are sequentially disposed in the first direction D1. The first and second pixels PX1 and PX2 form the first row, and the third and fourth pixels PX3 and PX4 form the second row.

Each of the first to fourth pixels PX1, PX2, PX3, and PX4 may include a first sub-pixel SPX1 and a second sub-pixel SPX2. The first and second sub-pixels SPX1 and SPX2 may be sequentially disposed in the first direction D1.

In some example embodiments, one of reference colors may be allocated to each of the pixel groups PXG, and the first to fourth pixels PX1, PX2, PX3, and PX4 in the pixel group PXG may have the allocated one color among the reference colors. For example, a green color may be allocated to one pixel group PXG. For example, the first to fourth pixels PX1, PX2, PX3, and PX4 may all have a green color filter.

In some example embodiments, each of the pixel groups PXG may have one color, and when the plurality of pixel groups PXG are arranged, the pixel groups PXG may be entirely formed in a Bayer pattern. For example, when four pixel groups PXG are arranged in a 2×2 matrix form, two pixel groups PXG in the first row may have blue and green colors, respectively, and two pixel groups PXG in the second row may have green and red colors, respectively.

Red, green, and blue (RGB), red, green, blue, and white (RGBW), cyan, magenta, and yellow (CMY), cyan, magenta, yellow, and black (CMYK), red, yellow, and blue (RYB), and infrared ray (RGBIR) may serve as examples of the plurality of reference colors. In some example embodiments, the first to third colors have a blue color B, a green color G, and a red color R, respectively. However, the present inventive concepts are not limited thereto.

The colors of the first to fourth pixels PX1, PX2, PX3, and PX4 may be implemented by color filters CF corresponding to the respective pixels PX. When an array constituted by the color filters CF corresponding to the respective pixels PX is referred to as a color filter array, the color filter array may include first to third color filters CF1, CF2, and CF3 corresponding to the pixels PX. According to some example embodiments, the first to third color filters CF1, CF2, and CF3 may represent a blue color, a green color, and a red color, respectively. The first color filter CF1 may correspond to the first pixel PX1, the second color filter CF2 may correspond to the second pixel PX2, the second color filter CF2 may correspond to the third pixel PX3, and the third color filter CF3 may correspond to the fourth pixel PX4. Hereinafter, for convenience of description, the description will be focused on the Bayer pattern, for example, the RGB pattern (or, the RGGB pattern). However, it should be noted that this does not limit the repetitive arrangement structures and patterns of other color filter arrays. That is, example embodiments of the present inventive concepts are not limited thereto, and the color filter array may be formed in various patterns including RGB, CYYM, CYGM, RGBW, RYYB, and ×-trans.

Referring to FIG. 3, the plurality of pixel groups included in the image sensor according to some example embodiments may include a pixel circuit PXC corresponding thereto. The pixel circuit PXC may include photodiodes PD1, PD2, PD3, and PD4 included in the plurality of unit pixels PX, respectively, and a plurality of semiconductor devices for processing charges generated by the photodiodes PD1, PD2, PD3, and PD4. For example, the pixel circuit PXC may include the first photodiode PD1, the second photodiode PD2, the third photodiode PD3, and the fourth photodiode PD4. The pixel circuit PXC may include first to fourth transfer transistors TX1, TX2, TX3, and TX4 corresponding to the plurality of photodiodes PD1, PD2, PD3, and PD4, respectively, a reset transistor RX, a selection transistor SX, and a drive transistor DX. The photodiodes PD1, PD2, PD3, and PD4 included in the pixel circuit PXC may share a floating diffusion region FD, the reset transistor RX, the selection transistor SX, and the drive transistor DX.

In some example embodiments, gate electrodes of the plurality of transistors TX1, TX2, TX3, TX4, RX, SX, and DX included in the pixel circuit PXC may be connected to drive signal lines, respectively. For example, the first to fourth transfer transistors TX1, TX2, TX3, and TX4 may operate by receiving transmission control signals TG1, TG2, TG3, and TG4 from a transmission control signal line, the reset transistor RX may operate by receiving a reset control signal RG from a reset control signal line, and the selection transistor SX may operate by receiving a selection control signal SG. However, this is illustrative, and without being limited to that illustrated in FIG. 2, the pixel circuit PXC according to some example embodiments may be designed in various ways. For example, the pixel circuit PXC may include semiconductor devices for processing charges generated by the photodiodes in units larger or smaller than the unit pixels PX.

In some example embodiments, one pixel circuit PXC may generate a first electrical signal from charges generated by photodiodes PD1, PD2, PD3, and PD4 included in the corresponding pixel circuit PXC and may output the first electrical signal to a first column line, and another pixel circuit may generate a second electrical signal from charges generated by photodiodes PD1, PD2, PD3, and PD4 included in the corresponding pixel circuit and may output the second electrical signal to a second column line. According to some example embodiments, two or more pixel circuits disposed adjacent to each other may share one first column line. Similarly, in some example embodiments, two or more other pixel circuits disposed adjacent to each other may share one second column line. In some example embodiments, the pixel circuits disposed adjacent to each other may share some semiconductor devices.

The first to fourth transfer transistors TX1, TX2, TX3, and TX4 may be connected with the first to fourth photodiodes PD1, PD2, PD3, and PD4, respectively. In some example embodiments, the first to fourth transfer transistors TX1, TX2, TX3, and TX4 may share the floating diffusion region FD. The first to fourth photodiodes PD1, PD2, PD3, and PD4 may generate charges in proportion to the amount of light incident from the outside and may accumulate the charges therein.

The first to fourth transfer transistors TX1, TX2, TX3, and TX4 may sequentially transmit the charges accumulated in the first to fourth photodiodes PD1, PD2, PD3, and PD4 to the floating diffusion region FD. To transmit the charges generated by one of the first to fourth photodiodes PD1, PD2, PD3, and PD4 to the floating diffusion region FD, the different transmission control signals TG1, TG2, TG3, and TG4 may be applied to the gate electrodes of the first to fourth transfer transistors TX1, TX2, TX3, and TX4. Accordingly, in some example embodiments, the floating diffusion region FD may accumulate the charges generated by at least one of the first to fourth photodiodes PD1, PD2, PD3, and PD4.

The reset transistor RX may periodically reset charges accumulated in the floating diffusion region FD. For example, electrodes of the reset transistor RX may be connected to the floating diffusion region FD and a power supply voltage VDD. When the reset transistor RX is turned on, charges accumulated in the floating diffusion region FD may be discharged due to a potential difference from the power supply voltage VDD, and the floating diffusion region FD may be reset. The voltage of the floating diffusion region FD may be equal to the power supply voltage VDD.

In some example embodiments, an operation of the drive transistor DX may be controlled depending on the amount of charges accumulated in the floating diffusion region FD. The drive transistor DX may serve as a source-follower buffer amplifier in combination with a current source disposed outside the unit pixel PX. For example, the drive transistor DX may amplify a potential change depending on the accumulation of charges in the floating diffusion region FD and may output the amplified potential change to an output line Vout.

The selection transistor SX may select unit pixels PX that are to be read in units of rows. When the selection transistor SX is turned on, an electrical signal output from the drive transistor DX may be transferred to the selection transistor SX.

The image sensor according to some example embodiments may provide an auto focus function in at least one of the plurality of unit pixels, based on the pixel circuit illustrated in FIG. 2. For example, the image sensor may provide the auto focus function in four directions (e.g., up, down, left, and right directions) using the first to fourth photodiodes PD1 to PD4.

For example, a logic circuit may provide an auto focus function in the up/down direction using pixel signals obtained from the first photodiode PD1 and the second photodiode PD2 and pixel signals obtained from the third photodiode PD3 and the fourth photodiode PD4. In some example embodiments, the logic circuit may provide an auto focus function in the left/right direction using pixel signals obtained from the first photodiode PD1 and the third photodiode PD3 and pixel signals obtained from the second photodiode PD2 and the fourth photodiode PD4. However, example embodiments of a pixel circuit of a unit pixel that provides an auto focus function is not necessarily limited to that illustrated in FIG. 2, and some devices may be added or omitted as needed.

The pixels of the pixel array having the above-described structure will be described in more detail as follows.

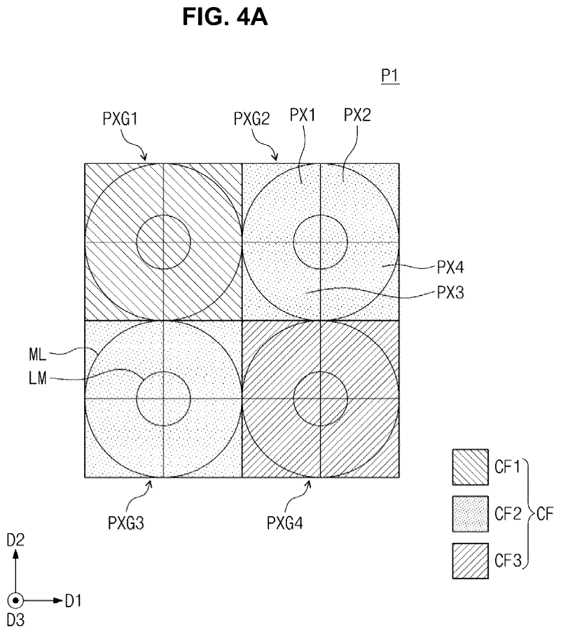

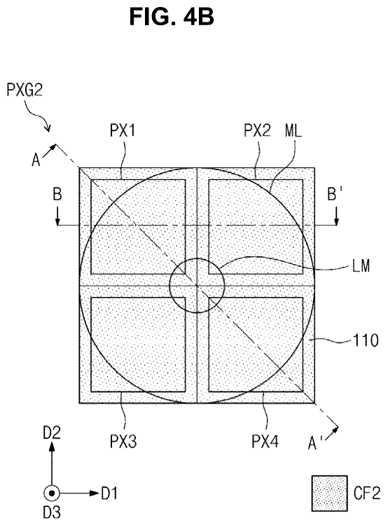

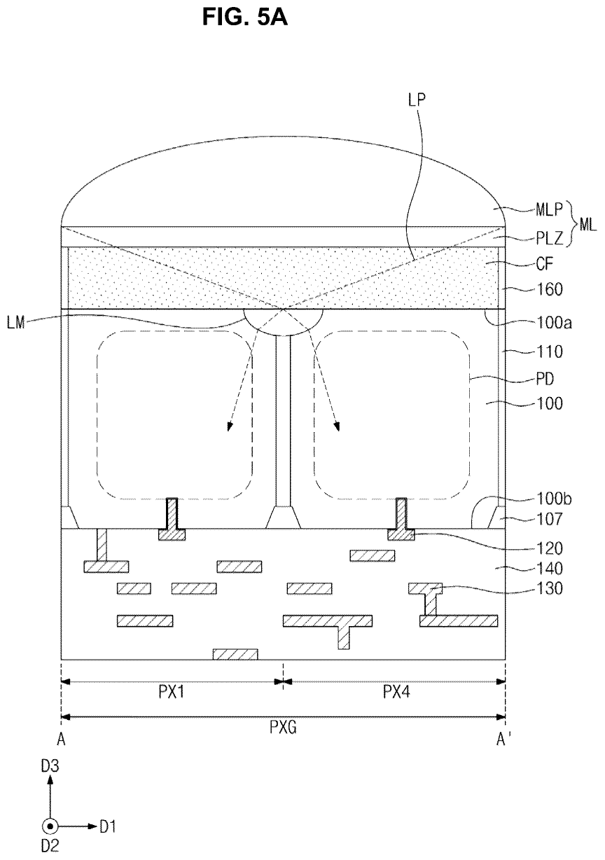

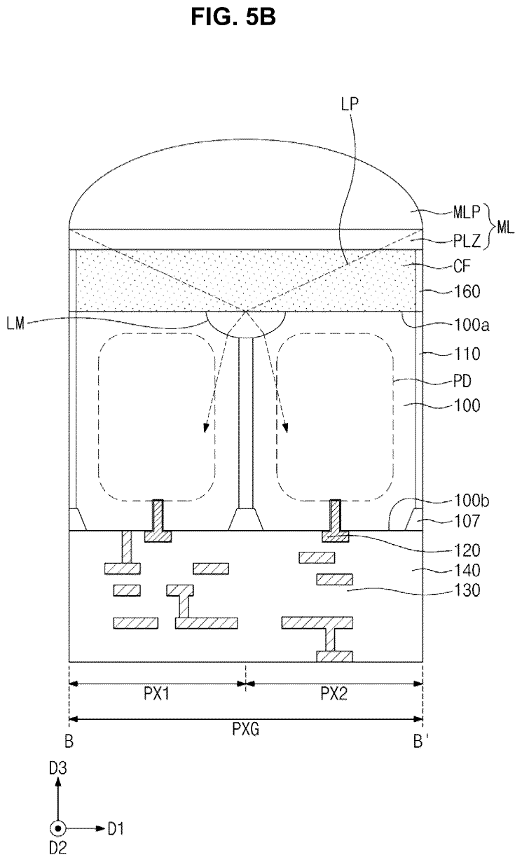

FIG. 4A is a plan view illustrating portion P1 in FIG. 2 according to some example embodiments, and FIG. 4B is a plan view illustrating a second pixel group in FIG. 4A according to some example embodiments. FIGS. 5A and 5B are sectional views taken along line A-A′ and line B-B′ of FIG. 4B according to some example embodiments.

Referring to FIGS. 4A, 4B, 5A, and 5B, the image sensor according to some example embodiments includes a plurality of photodiodes PD provided within a semiconductor substrate 100 for respective pixels PX, color filters CF (e.g., CF1, CF2, and CF3) that are provided on the photodiodes PD and that have at least two or more types of different colors, micro lenses ML that are provided on the color filters CF and that concentrate light incident toward the photodiodes PD through the color filters CF, and optical path changing members LM that change the path of light travelling toward the photodiodes PD through the micro lenses ML.

In some example embodiments, an additional non-illustrated component may or may not be interposed between the components of the image sensor according to some example embodiments, and for convenience of description, the following description will be focused on main components. For example, an additional insulating layer or a protective layer may be provided between the semiconductor substrate 100 and the color filters 100 and between the color filters CF and the micro lenses ML, but example embodiments are not limited thereto.

The semiconductor substrate 100 includes a first surface 100a disposed in a direction in which light is incident and a second surface 100b facing away from the first surface 100a. For example, the first surface 100a of the semiconductor substrate 100 of the present inventive concepts is a light incident surface.

The semiconductor substrate 100 may be, for example, a semiconductor substrate 100 including a semiconductor material, for example, a Group IV semiconductor. For example, the Group IV semiconductor may include silicon, germanium, or silicon-germanium. For example, the semiconductor substrate 100 may be provided as a bulk wafer, an epitaxial layer, a silicon on insulator (SOI) layer, or a semiconductor on insulator (SeOI) layer. The semiconductor substrate 100 may include, for example, impurity regions (not illustrated). For example, the semiconductor substrate 100 may be implemented with a p-type silicon semiconductor substrate 100. In some example embodiments, the semiconductor substrate 100 may include a p-type bulk semiconductor substrate 100 and a p-type or n-type epitaxial layer grown on the p-type bulk semiconductor substrate 100. Alternatively, in some example embodiments, the semiconductor substrate 100 may include an n-type bulk semiconductor substrate 100 and a p-type or n-type epitaxial layer grown on the n-type bulk semiconductor substrate 100. In some example embodiments, the semiconductor substrate 100 may be implemented with an organic plastic semiconductor substrate 100. For example, the image sensor may be a backside illumination type CMOS image sensor in which light is incident on the first surface 100a of the semiconductor substrate 100.

Although not illustrated, in some example embodiments, a passivation layer including a plurality of layers stacked one above another may be provided on the first surface 100a of the semiconductor substrate 100. For example, the passivation layer may include at least two of an aluminum oxide layer, a hafnium oxide layer, a tantalum oxide layer, a zirconium oxide layer, a silicon oxy nitride layer, a silicon oxide layer, and a silicon nitride layer, but example embodiments are not limited thereto. In some example embodiments, the passivation layer may include a fixed charge layer and/or an anti-reflection layer. For example, the anti-reflection layer may adjust a refractive index such that incident light travels toward the photodiodes PD at high transmittance.

In some example embodiments, the color filters CF are disposed behind the micro lenses ML with respect to a travel path of light. The color filters CF may be provided between the semiconductor substrate 100 and the micro lenses ML. The color filters CF may pass light having specified reference colors, for example, light having specified wavelength ranges.

In some example embodiments, the color filters CF may be disposed on the passivation layer and a grid layer 160 above the photodiodes PD. For example, the color filters CF may pass light having specific wavelengths and may allow the light to reach the photodiodes PD (PD1, PD2, PD3, and PD4) under the color filters CF. The color filters CF may be implemented with a color filter array including a red filter, a green filter, and a blue filter. The color filters CF may be formed of, for example, a material obtained by mixing a pigment containing metal or metal oxide with a resin.

The micro lenses ML may serve to refract and/or concentrate incident light that is incident to the photodiodes PD. In some example embodiments of the present inventive concepts, the plurality of micro lenses ML may be provided on the semiconductor substrate 100 and may correspond to respective pixel groups PXG in a one-to-one manner. For example, a plurality of pixels PX (e.g., first to fourth pixels PX1, PX2, PX3, and PX4) in one pixel group PXG may share one micro lens ML. The micro lenses ML may be provided in a convex lens shape so as to receive and concentrate light as much as possible depending on the direction in which the light is incident, for example, the angle of incidence of the light.

According to some example embodiments, the micro lenses ML may be formed of a transparent polymer material. The micro lenses ML may be formed of, for example, a transparent photosensitive material or a transparent thermosetting resin. The micro lenses ML may be formed of, for example, a TMR-based resin (manufactured by Tokyo Ohka Kogyo, Co.) or an MFR-based resin (manufactured by Japan Synthetic Rubber Corporation). However, example embodiments are not limited thereto, for example, the micro lenses ML may be formed of various materials.

In some example embodiments, the micro lenses ML may include planarization layers PLZ provided on the color filters CF and micro lens parts MLP provided on the planarization layers PLZ. The planarization layers PLZ are provided to flatten uneven upper surfaces of the color filters CF. In some example embodiments of the present inventive concepts, the planarization layers PLZ and the micro lens parts MLP may be formed as separate components through separate processes using separate materials. However, example embodiments are not limited thereto, and, for example, the planarization layers PLZ and the micro lens parts MLP may be formed of the same material and may be integrally formed with each other. In the following example embodiments, for convenience of description, the planarization layer PLZ and the micro lens part MLP are collectively referred to as the micro lens ML that is one component.

In some example embodiments, one micro lens ML may be provided for one pixel group PXG including the first to fourth pixels PX1, PX2, PX3, and PX4. For example, the first to fourth pixels PX1, PX2, PX3, and PX4 in the one pixel group PXG may share the one micro lens ML.

The photodiodes PD may be disposed behind the micro lens ML and the color filter CF and may correspond to photoelectric conversion devices. The photodiodes PD may absorb incident light and may generate and accumulate charges corresponding to the amount of the light.

In some example embodiments of the present inventive concepts, the photodiodes PD may be described as examples of the photoelectric conversion devices. However, example embodiments are not limited thereto, and, for example, photo transistors, photo gates, pinned photodiodes (PPDs), and at least one of combinations thereof may be used instead of the photodiodes PD as the photoelectric conversion devices. For example, when the photodiodes PD are used as the photoelectric conversion devices as in the present inventive concepts, the photodiodes PD may include an impurity region having a conductive type different from that of the semiconductor substrate 100 and may form a PN junction with a well region within the semiconductor substrate 100. When light reaches the photodiodes PD, the photodiodes PD may output electrical signals corresponding to the incident light by a photoelectric effect. The electrical signals may generate charges (or, currents) depending on the intensity (or, amount) of the received light.

According to some example embodiments, the optical path changing member LM is used to change the path of at least a portion of incident light when the incident light travels toward the photodiodes PD through the micro lens ML. The optical path changing member LM is provided between the semiconductor substrate 100 and the color filter CF. Description thereabout will be given below.

In some example embodiments of the present inventive concepts, each pixel PX may further include device isolators 107, pixel isolators 110, pixel electrodes 120 disposed within an insulating layer 140, and a grid layer 160 disposed on the semiconductor substrate 100.

The device isolators 107 may include an insulating material and may be disposed within the semiconductor substrate 100 at a certain depth from the second surface 100b of the semiconductor substrate 100. In some example embodiments, each of the device isolators 107 may be omitted depending on the configuration of the corresponding pixel PX.

The pixel isolators 110 may be disposed within the semiconductor substrate 100 below the boundary of each pixel PX. The pixel isolators 110 may be connected with the device isolators 107 on the second surface 100b. However, in some example embodiments, the arrangement of the pixel isolators 110 within the semiconductor substrate 100 in the third direction D3 may be changed in various ways. For example, the pixel isolators 110 may be disposed to surround the photodiodes PD. However, example embodiments of a relative arrangement relationship between the pixel isolators 110 and the photodiodes PD are not limited to that illustrated and, according to some example embodiments, may be changed in various different ways. In some example embodiments, the pixel isolators 110 may include an insulating material or a conductive material. For example, when the pixel isolators 110 include conductive material, an insulating layer disposed between the pixel isolators 110 and the semiconductor substrate 100 may be further included.

The pixel electrodes 120 may be disposed between the photodiodes PD and a wiring structure 130. The pixel electrodes 120 may constitute pixel circuits of the pixels PX. For example, the pixel electrodes 120 may include a transfer gate constituting a transfer transistor. The transfer gate may be a vertical transistor gate including a portion extending into the semiconductor substrate 100 from the second surface 100b of the semiconductor substrate 100. The pixel electrodes 120 may further include a floating diffusion region FD within the semiconductor substrate 100 and gates on the second surface 100b of the semiconductor substrate 100, in addition to the transfer gate. The gates may constitute a source follower transistor, a reset transistor, and a select transistor.

The grid layer 160 may be disposed between the color filters CF on the passivation layer to separate the color filters CF. The grid layer 160 may be disposed on the passivation layer (not illustrated) and may be disposed below the boundary of each pixel PX. The grid layer 160 may be disposed on the pixel isolators 110 in the third direction D3 that is a direction perpendicular to one surface of the semiconductor substrate 100. The grid layer 160 may be implemented with multiple layers and may include a metallic material, for example, at least one of titanium (Ti), titanium oxide, tantalum (Ta), and tantalum oxide, but example embodiments are not limited thereto. Furthermore, the grid layer 160 may be an insulating layer that is a low refractive index (LRI) layer, and the refractive index may range, for example, from about 1.1 to about 1.8. The grid layer 160 may include an insulating material, for example, oxide or nitride including silicon (Si), aluminum (Al), or a combination thereof. For example, the grid layer 160 may include silicon oxide having a porous structure or silica nano particles having a reticulated structure.

According to some example embodiments, when the terms “about” or “substantially” are used in this specification in connection with a numerical value, it is intended that the associated numerical value include a tolerance of +10% around the stated numerical value. When ranges are specified, the range includes all values therebetween such as increments of 0.1%.

As described above, according to some example embodiments, among the plurality of pixels PX, at least two pixels PX may share one micro lens ML among the micro lenses ML. In some example embodiments, light incident through the corresponding micro lens ML may have a focus on the center of the at least two pixels PX that share the corresponding micro lens ML, and thus the light is concentrated on the center of the at least two pixels PX. For example, according to some example embodiments of the present inventive concepts, the pixels PX corresponding to the one micro lens ML correspond to one pixel group PXG including the first to fourth pixels PX1, PX2, PX3, and PX4, and the light incident to the one micro lens ML is concentrated on the center of the first to fourth pixels PX1, PX2, PX3, and PX4. However, in some example embodiments, the pixel isolator 110 dividing the pixels PX from each other is provided at the center of the at least two pixels PX sharing the corresponding micro lens ML as described above, for example, at the center of the first to fourth pixels PX1, PX2, PX3, and PX4. Accordingly, light that has to travel toward the photodiodes PD of the corresponding pixels PX, for example, the photodiodes PD of the first to fourth pixels PX1, PX2, PX3, and PX4 may be concentrated on the pixel isolator 110 and thus may be absorbed into the pixel isolator 110. The absorption of the light into the pixel isolator 110 significantly reduces the light receiving efficiency of the photodiodes PD. In some example embodiments, the pixel isolator 110 may include a light absorbing material to prevent light travelling toward the pixel isolator 110 from travelling toward an adjacent pixel PX to cause crosstalk. In some example embodiments, absorption of incident light may be intensified, and the light receiving efficiency may also be further reduced.

In some embodiments of the present inventive concepts, the optical path changing member LM is provided at the position in which the focus of the micro lens ML is located. For example, when viewed from above the plane (e.g., as illustrated in FIG. 4B), the optical path changing member LM may be provided to overlap the focus formed by the micro lens ML. In some example embodiments (e.g., as illustrated in FIG. 4B), when viewed from above the plane, the optical path changing member LM may be provided to overlap the pixel isolator 110. Accordingly, in some example embodiments, the optical path changing member LM changes the path of light travelling toward the pixel isolator 110. The changed light may travel toward a region other than the pixel isolator 110, for example, the photodiodes PD.

In some example embodiments, the optical path changing member LM uses refraction, diffraction, and/or scattering to effectively change the path of light. For example, the optical path changing member LM uses an effect by which light is refracted, diffracted, and/or scattered at an interface between materials having different refractive indexes (hereinafter, refraction will be described as an example). According to some example embodiments, the optical path changing member LM includes a curved surface having various shapes, and the curved surface extends from the first surface 100a of the semiconductor substrate 100. In some example embodiments, to induce refraction of light, the optical path changing member LM may use materials that are disposed on opposite sides of the curved surface and that have different refractive indexes. Accordingly, in some example embodiments, while transmitting through the optical path changing member LM, light is refracted in a direction different from the direction in which the light originally travels, and the travel direction of the light is changed through the refraction. For example, as illustrated in FIG. 5A, the path LP of light transmitted through the corresponding micro lens ML according to some example embodiments is simply illustrated by a dash-dot-dash line.

In some example embodiments of the present inventive concepts, the optical path changing member LM may have a curved surface that is concave or convex in the direction from the first surface 100a toward the second surface 100b of the semiconductor substrate 100. The optical path changing member LM may be formed by processing the first surface 100a of the semiconductor substrate 100. For example, as illustrated, the optical path changing member LM may have a depression recessed in the direction from the first surface 100a toward the second surface 100b. The depression may be filled with a material different from that of the semiconductor substrate 100 so as to have a refractive index different from the refractive index of the semiconductor substrate 100. For example, the depression may be filled with an insulating material different from the material of the semiconductor substrate 100. The insulating material may include not only silicon oxide, silicon nitride, or silicon oxy nitride but also various inorganic materials and various organic materials such as polyvinyl alcohol. The refractive index of light passing through the optical path changing member LM may be determined depending on the selection of the insulating material.

In some example embodiments, for example as illustrated in FIGS. 4A, 4B, 5A, and 5B, the optical path changing member LM may be a portion of a sphere and may be provided in a circular shape when viewed from above the plane. In some example embodiments, even though the optical path changing member LM is not a portion of a sphere, the optical path changing member LM may have a symmetrical shape, for example, a rotationally symmetrical shape, with respect to a line passing through the center.

In some example embodiments of the present inventive concepts, the optical path changing member LM may have various shapes, but the optical path changing member LM may have a curved surface without a bent portion such that light is evenly refracted and radiated in various directions toward the photodiodes PD. For example, when the optical path changing member LM has a curved surface, concentration of light on a bent portion only in one direction may be reduced.

According to some example embodiments of the present inventive concepts, the optical path changing member LM may increase light efficiency by inducing light capable of being absorbed into the pixel isolator 110 to travel toward the photodiodes PD as much as possible at the same time as increasing light concentrating efficiency. In some example embodiments, the optical path changing member LM may prevent crosstalk by reducing interference caused by plain light.

Furthermore, according to some example embodiments of the present inventive concepts, the optical path changing member LM may be directly formed on the first surface 100a that is a light incidence surface of the semiconductor substrate 100, and thus it may not be advantageous, necessary, or desirable to change the path of light through an additional component. An additional component for refraction of light, for example, may be a separate optical path changing means added between the semiconductor substrate and the color filters, a shape for an optical path change that is formed by making the color filters themselves subject to patterning, or additional micro lenses that may increase an optical path and may require an additional layer (e.g., an additional insulating layer) for disposing the additional component. The additional component may increase the number of layers through which light has to transmit to reach the photodiodes and therefore may cause an increase in thickness and a reduction in light efficiency. The present inventive concepts solves this problem without the additional optical path changing means.

In some example embodiments, one pixel group PXG may include the first to fourth pixels PX1, PX2, PX3, and PX4 different from one another, and photoelectric conversion signals of the photodiodes PD included in the respective pixels PX may be independently read. Auto focusing may be performed by detecting a phase difference using the arrangement relationship between the different photodiodes PD included in the respective pixels PX. The detection of the phase difference may be performed in each of the directions in which the photodiodes PD within the first to fourth pixels PX1, PX2, PX3, and PX4 are arranged. Since the first to fourth pixels PX1, PX2, PX3, and PX4 are arranged in the first direction D1 and the second direction D2 in some example embodiments, the detection of the phase difference may be performed in both the horizontal direction and the vertical direction.

As described above, in some example embodiments of the present inventive concepts, the micro lenses ML may sense an image and may detect a phase difference depending on the position of light incident to the same lens, and auto focusing using the phase difference is possible.

In some example embodiments, each of the pixel groups PXG may include the first to fourth pixels PX1, PX2, PX3, and PX4 arranged in a 2×2 matrix. However, the present inventive concepts are not limited thereto. Although not separately illustrated, each of the pixel groups PXG may include first to ninth pixels arranged in a 3×3 matrix form in some example embodiments of the present inventive concepts.

As apparent to one of ordinary skill in the art, various changes or modifications may be made to the image sensor according to some example embodiments of the present inventive concepts without departing from the spirit and scope of the present inventive concepts. For convenience of description, the following descriptions will be focused on differences from the above-described example embodiments.

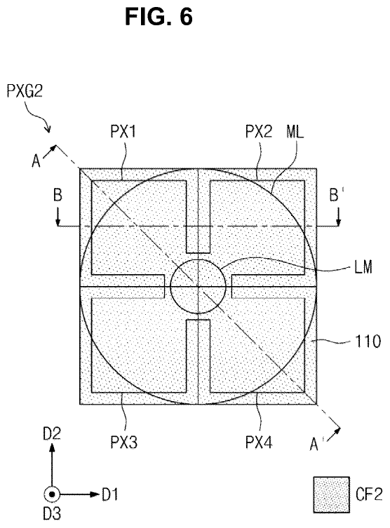

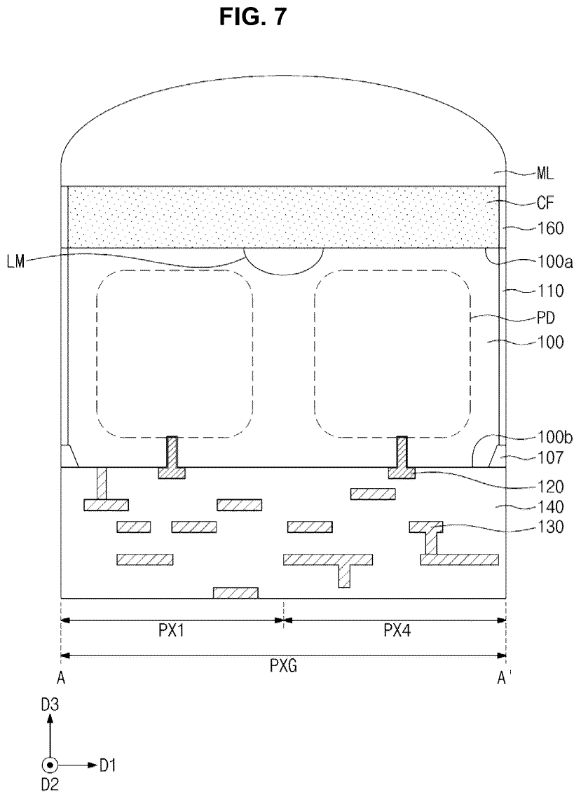

FIG. 6 illustrates an image sensor according to some example embodiments, where FIG. 6 is a plan view corresponding to the second pixel group PXG2 of FIG. 4A. FIG. 7 is a sectional view taken along line A-A′ of FIG. 6 according to some example embodiments.

Referring to FIGS. 6 and 7, in the image sensor according to some example embodiments of the present inventive concepts, portions of pixel isolators 110 may be removed between two or more pixels PX adjacent to each other, and when viewed from above the plane, an optical path changing member LM may be spaced apart from the pixel isolators 110. For example, when viewed from above the plane, the optical path changing member LM may be disposed in a region from which the portions of the pixel isolators 110 are removed. For example, a first direction pixel isolator 110 and a second direction pixel isolator 110 provided between two pixels PX adjacent to each other in one pixel group PXG may cross each other. The portions of the pixel isolators 110 that correspond to the intersection region are at least partially removed, and the optical path changing member LM is provided in the removed region.

The structure corresponds to a configuration in which first to fourth pixels PX1, PX2, PX3, and PX4 share a floating diffusion region. For example, the removed portion of the intersection region may be completely removed from the first surface 100a to the second surface 100b of the semiconductor substrate 100 in the third direction D3. A floating diffusion region shared by the plurality of unit pixels PX included in the pixel group PXG is formed in the removed portion of the intersection region. In this configuration, electrons may move between the two adjacent pixels PX through the removed portion of the intersection region. The movement of the electrons may be controlled by a potential profile formed in a semiconductor substrate 100 depending on the removed length and a manufacturing process.

According to some example embodiments, since the optical path changing member LM is provided in the intersection region, light may be effectively transferred to the plurality of adjacent pixels PX, for example, the first to fourth pixels PX1, PX2, PX3, and PX4. Accordingly, the light receiving efficiency of photodiodes PD may be maximized.

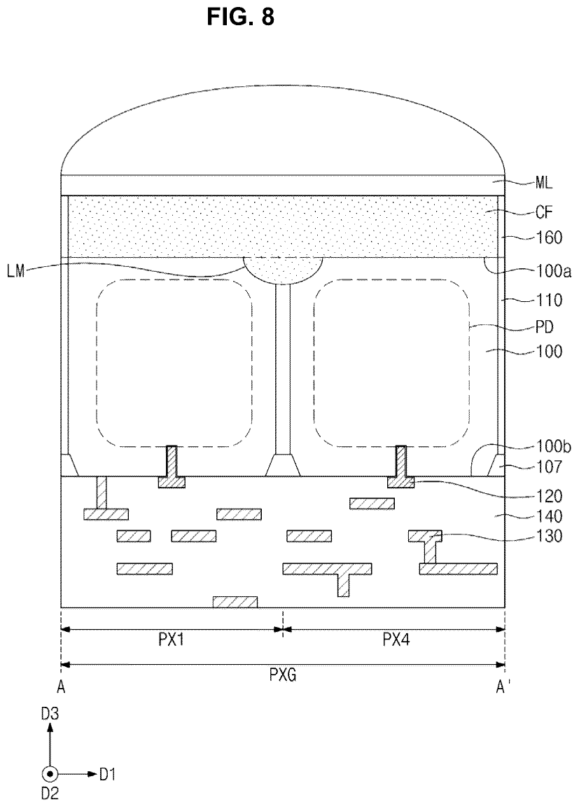

FIGS. 8 to 11 illustrate image sensors according to some example embodiments, where FIGS. 8 to 11 are sectional views corresponding to line A-A′ of FIG. 4A.

Referring to FIG. 8, according to some example embodiments of the present inventive concepts, various materials may be used to fill a depression of an optical path changing member LM. For example, one color filter CF among color filters CF may fill the depression of the optical path changing member LM.

The refractive index of the color filter CF is different from the refractive index of a semiconductor substrate 100, and an optical path is easily changed due to a refraction effect of incident light depending on the difference in refractive index. In some example embodiments, when the depression is filled with the color filter CF, a step of filling the depression with a separate insulating material may be omitted, and thus the image sensor may be easily manufactured. In some example embodiments, a reduction in light transmittance when a plurality of layers are stacked one above another as well as a decrease in the length of an optical path may be minimized.

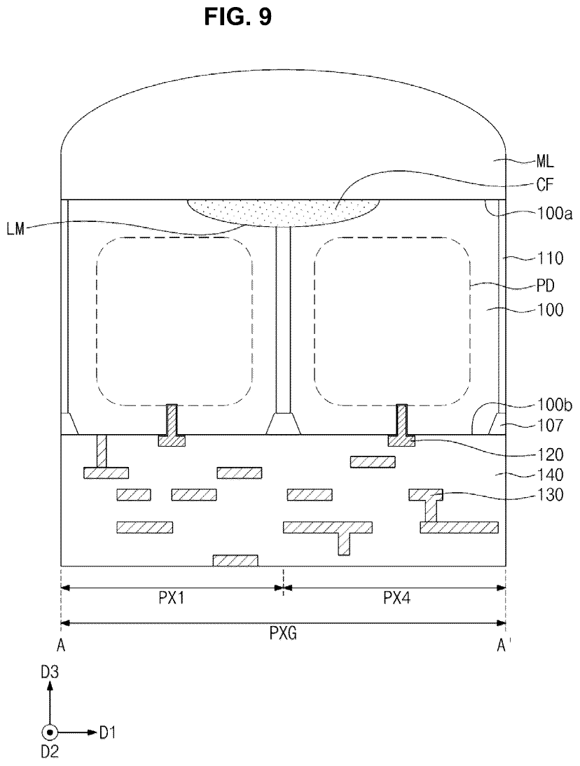

Referring to FIG. 9, in the image sensor according to some example embodiments of the present inventive concepts, a color filter CF may not be formed as a separate layer, but may be formed only within a depression of an optical path changing member LM using the optical path changing member LM. For example, among color filters CF, one color filter CF corresponding to a corresponding pixel PX may fill only the depression, and a micro lens ML may be directly disposed on the depression.

For example, the area of the optical path changing member LM on the plane may be diversely changed. As illustrated in FIG. 9, in some example embodiments, when viewed from above the plane, at least a portion of the color filter CF of the corresponding pixel PX may overlap the micro lens ML corresponding to a corresponding pixel (PX) group. For example, when light is provided to photodiodes PD without passing through the color filter CF, the amount of light toward the photodiodes PD may be increased. Accordingly, the amount of light incident to the photodiodes PD may be controlled by adjusting a portion that does not overlap the portion where the color filter CF and the micro lens ML overlap each other.

In some example embodiments of the present inventive concepts, the optical path changing member LM may have a curved surface in various shapes different from that in the above-described example embodiments in a direction from a first surface 100a toward a second surface 100b of a semiconductor substrate 100. The optical path changing member LM according to some example embodiments of the present inventive concepts may have various shapes within the limit of controlling refraction of light to redistribute the light to the corresponding photodiodes PD as much as possible, or alternatively, as much as desired, without absorption of the light into pixel isolators 110.

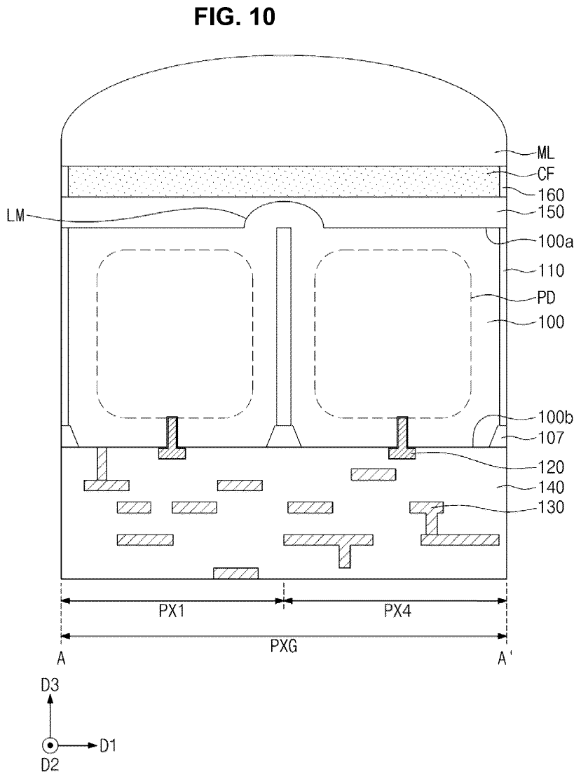

Referring to FIG. 10, in some example embodiments, an optical path changing member LM may include a protrusion that protrudes in a direction opposite to a direction from a first surface 100a toward a second surface 100b, for example, in the third direction D3. In some example embodiments, the inside of the protrusion may be filled with the same material as that of a semiconductor substrate 100. For example, likewise to the semiconductor substrate 100, the protrusion may be formed of a semiconductor material, for example, a Group IV semiconductor. The Group IV semiconductor may include silicon, germanium, or silicon-germanium, and the protrusion may be integrally formed with the semiconductor substrate 100. In some example embodiments, an interlayer film 150 covering the protrusion may be provided between the protrusion and a color filter CF.

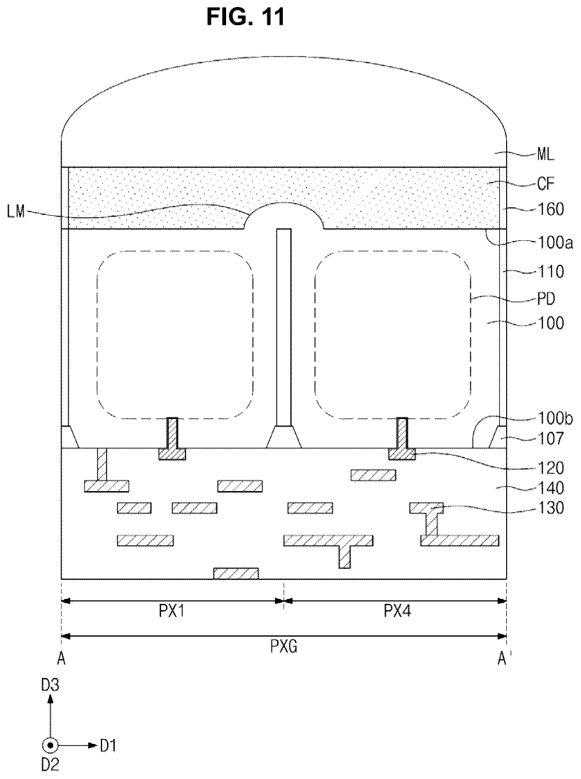

Referring to FIG. 11, in some example embodiments, an optical path changing member LM may have a curved surface having a shape protruding in the third direction D3 similar to that illustrated in FIG. 10, and the inside of the protrusion may be filled with the same material as that of a semiconductor substrate 100. However, unlike in some example embodiments, for example as illustrated in FIG. 10, the interlayer film 150 may be omitted, and a color filter CF may be provided on the semiconductor substrate 100. Since the interlayer film 150 is omitted in some example embodiments, the amount of light incident to photodiodes PD may be increased.

In the image sensor according to some example embodiments, the optical path changing member LM may have a symmetrical shape as described above. However, without being limited thereto, the optical path changing member LM may be modified in various different ways and to have various different shapes.

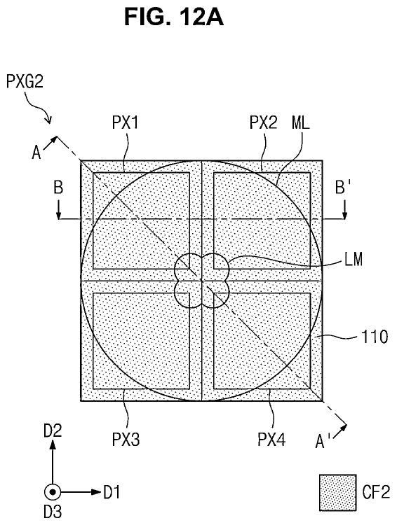

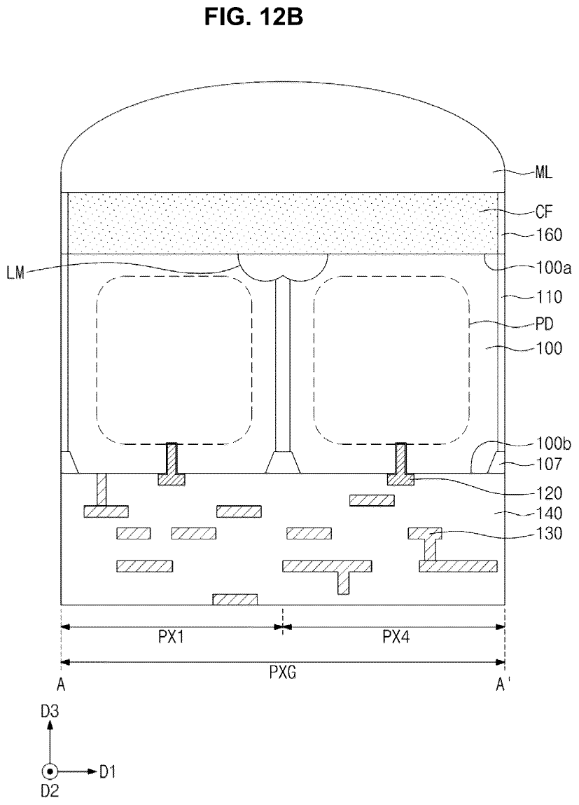

FIG. 12A illustrates an image sensor according to some example embodiments, where FIG. 12A is a plan view corresponding to the second pixel group of FIG. 4A. FIG. 12B is a sectional view taken along line A-A′ of FIG. 12A according to some example embodiments.

Referring to FIGS. 12A and 12B, in some example embodiments, an optical path changing member LM may not have a circular shape when viewed from above the plane and may be provided in a shape that has line symmetry in a specific or alternatively, desired direction. For example, to allow light to evenly travel toward pixels PX adjacent to the optical path changing member LM rather than the pixel isolators 110 disposed around the optical path changing member LM, the optical path changing member LM may have a shape that further protrudes toward corresponding photodiodes PD. For example, as illustrated in FIG. 12A, the optical path changing member LM, when viewed from above the plane, may have a shape further protruding in diagonal directions of first to fourth pixels PX1, PX2, PX3, and PX4, for example, a shape similar to the shape of a four-leaf clover. For example, the optical path changing member LM may have a shape protruding toward the corresponding photodiodes PD even when viewed in the sectional view as illustrated by FIG. 12B. For example, the optical path changing member LM may have a shape having line symmetry in the first direction D1 and the second direction D2 when viewed from above the plane (e.g., as illustrated in FIG. 12A) and may have a shape having line symmetry in the third direction D3 when viewed in the sectional view (e.g., as illustrated in FIG. 12B).

However, although the shape of the optical path changing member LM has been described according to some example embodiments, and the present inventive concepts are not limited thereto. For example, the optical path changing member LM may be asymmetrically provided depending on the shape or size of the adjacent pixels PX. Alternatively, in some example embodiments, when a corresponding micro lens ML has an asymmetrical shape even though the corresponding pixels PX have the same size and shape, the optical path changing member LM may also be asymmetrically provided.

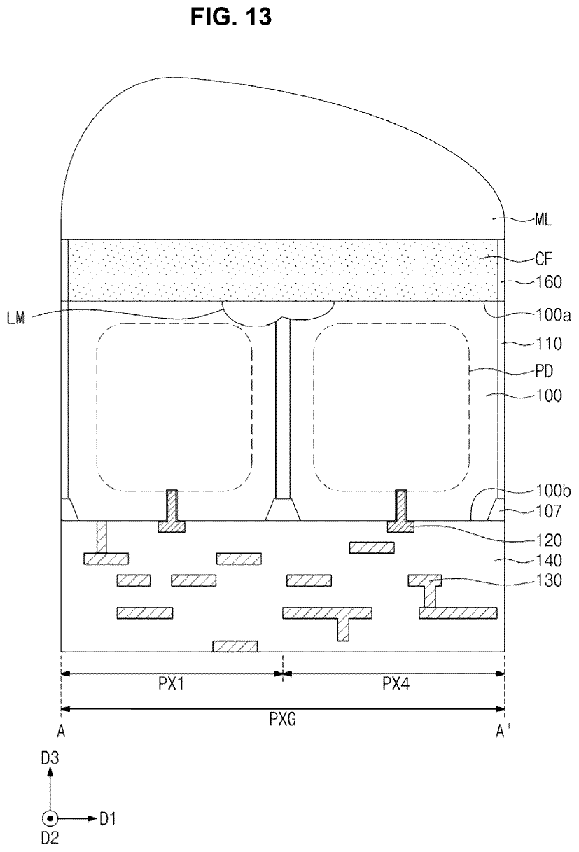

FIG. 13 illustrates an image sensor according to some example embodiments, where FIG. 13 is a sectional view taken along line A-A′ in a plan view corresponding to the second pixel group PXG2 of FIG. 4A.

Referring to FIG. 13, in the image sensor according to some example embodiments, at least one micro lens ML may have an asymmetrical shape. In some example embodiments, when the micro lens ML has an asymmetrical shape, a focus may be formed at a position other than pixel isolators 110, and therefore sufficient light may not be distributed to pixels PX adjacent to each other. Accordingly, in some example embodiments, an optical path changing member LM may be asymmetrically formed to correspond to the focus of the corresponding asymmetrical micro lens ML, and thus the path of light transmitting through the asymmetrical micro lens ML may be effectively changed. In some example embodiments, when the asymmetrical micro lens ML is used, it is advantageous for concentrating light incident on a first surface 100a of a semiconductor substrate 100 in an inclined state rather than in a perpendicular direction. Accordingly, in some example embodiments, even though light is incident to the image sensor in a state of being inclined at a certain angle, light sensing efficiency may be increased, and phase-difference detection efficiency of light provided to the adjacent pixels PX (for example, first to fourth pixels PX1, PX2, PX3, and PX4) may be increased. Thus, auto focusing performance may also be improved.

In some example embodiments of the present inventive concepts, the optical path changing member LM may be provided in different sizes depending on the shape or size of the adjacent pixels PX or pixel groups PXG, or may be provided in different sizes in consideration of characteristics depending on the colors of the corresponding pixels PX.

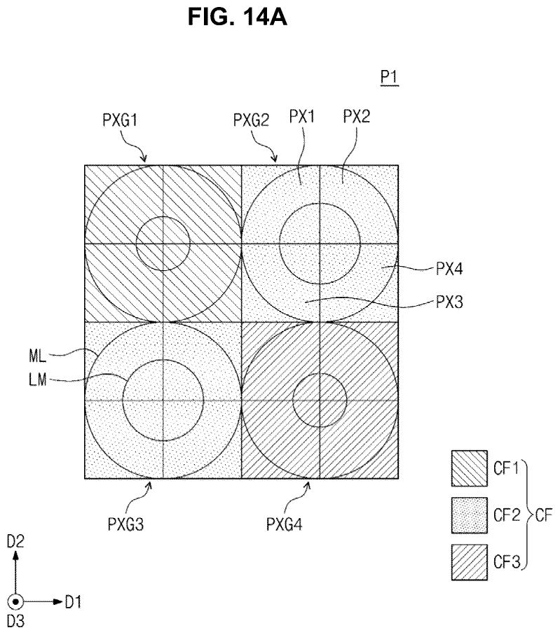

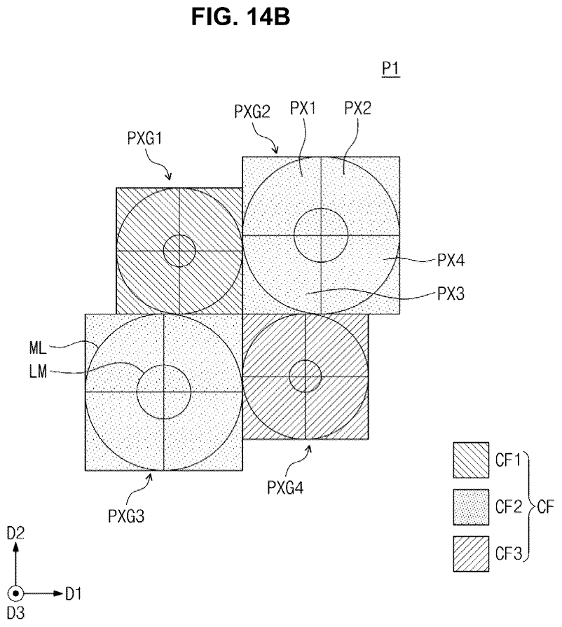

FIGS. 14A and 14B are plan views corresponding to the second pixel group PXG2 of FIG. 4A in an image sensor according to some example embodiments.

Referring to FIGS. 14A and 14B, in some example embodiments, optical path changing members LM are provided within first to fourth pixel groups PXG1, PXG2, PXG3, and PXG4, respectively. The optical path changing members LM may be provided in different sizes depending on colors or areas.

For example, when the first to fourth pixel groups PXG1, PXG2, PXG3, and PXG4 are arranged in a 2×2 matrix form, the second and third pixel groups PXG2 and PXG3 may be expanded such that the second and third pixel groups PXG2 and PXG3 have a larger micro lens ML than the other pixel groups or the pixel group themselves have a larger area. In some example embodiments, the first and/or fourth pixel groups PXG1 and/or PXG4 may be reduced such that the first and/or fourth pixel groups PXG1 and/or PXG4 have a smaller micro lens ML or a smaller area than the second and third pixel groups PXG2 and PXG3. For example, as illustrated in FIG. 14A, the first pixel group PXG1 may correspond to blue as a first color filter CF1, the second pixel group PXG2 may correspond to green as a second color filter CF2, the third pixel group PXG3 may correspond to green as a second color filter CF2, and the fourth pixel group PX4 may correspond to red as a third color filter CF3. Through the change of the areas, photodiodes may more easily convert light having a specific color. In some example embodiments, the sizes or shapes of the optical path changing members LM may be provided to correspond to the color filters CF, and thus light receiving efficiency may be improved.

In some example embodiments, light travelling toward the photodiodes PD through the micro lenses ML and the color filters CF may have chromatic aberration depending on colors. Furthermore, the absorbance of the light into a semiconductor substrate 100 may vary. Accordingly, in some example embodiments, the optical path changing members LM may be formed in view of that. For example, light transmitting through the micro lenses ML may be focused at different positions for respective colors, uneven light detection may occur due to chromatic aberration depending on the colors when the optical path changing members LM are formed in the same size at the same location, and the semiconductor substrate 100 having the photodiodes PD formed therein may have different light absorption rates depending on the colors. Accordingly, in some example embodiments, in consideration of the characteristics for the respective colors, the optical path changing members LM having different sizes and shapes may be provided for the pixel groups PXG corresponding to the respective colors. Thus, light receiving efficiency may be improved as much as possible.

The image sensors according to some example embodiments of the inventive concepts that have the above-described structures may be manufactured by various methods. In order to avoid repetitive descriptions, methods for manufacturing the image sensors according to some example embodiments, e.g., as illustrated in FIGS. 5A, 8, 9, and 10 will be described as examples. However, various changes or modifications may be made to the methods for manufacturing the image sensors according to example embodiments of the inventive concepts without departing from the spirit and scope of the present inventive concepts.

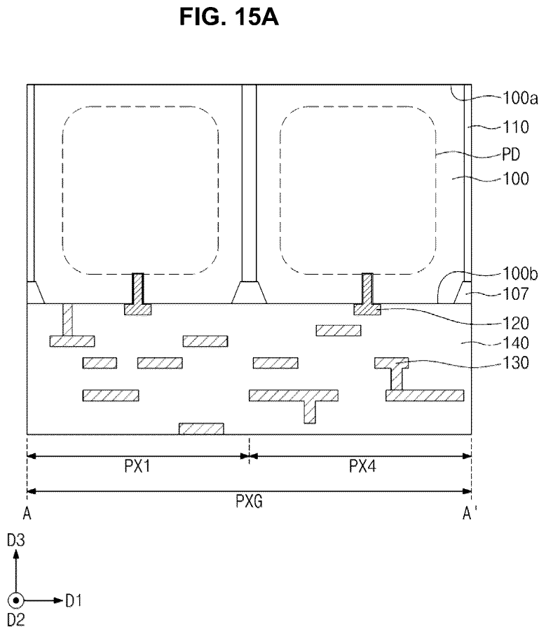

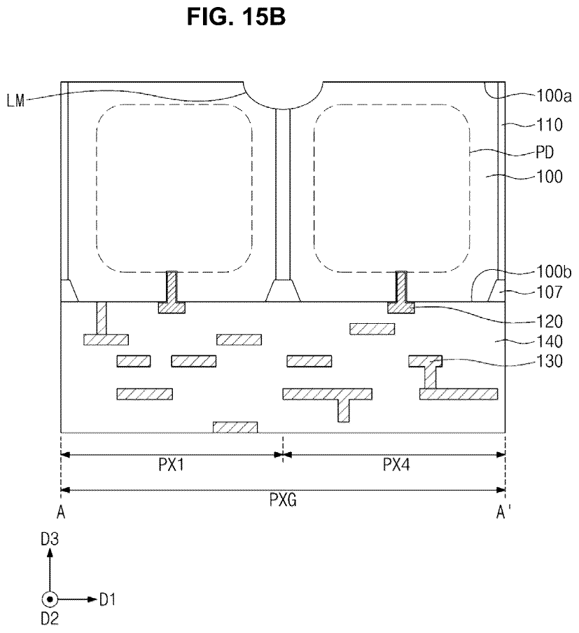

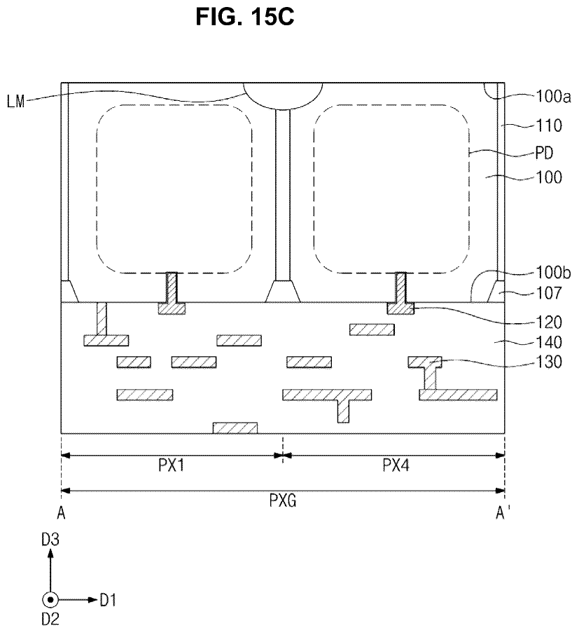

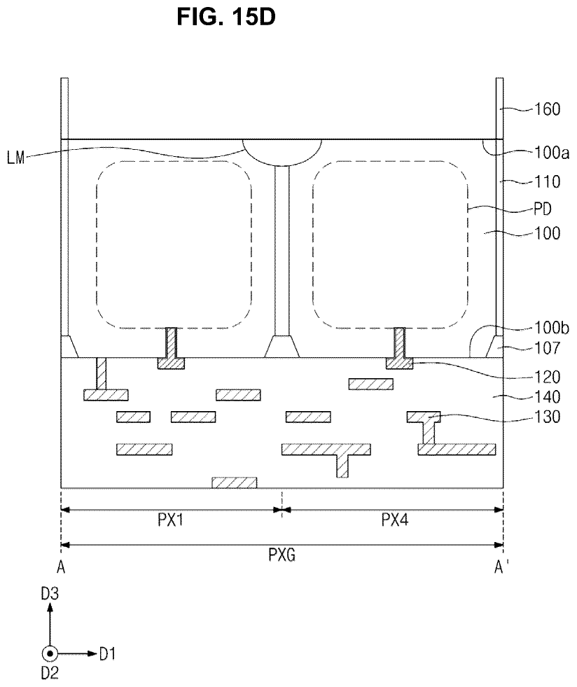

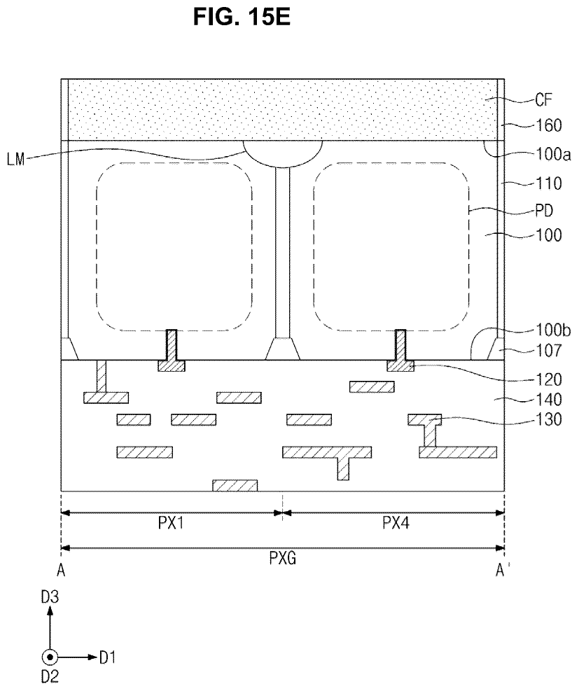

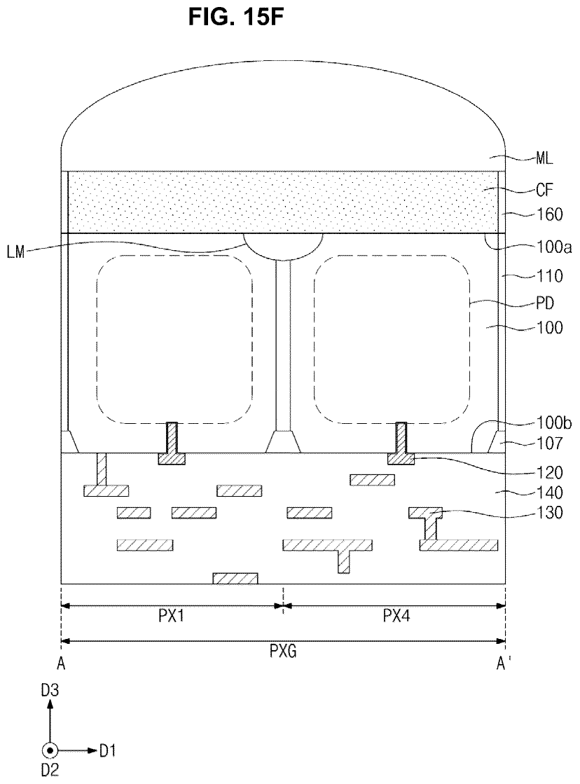

FIGS. 15A to 15F are sectional views sequentially illustrating a method for manufacturing the image sensor illustrated in FIG. 5A according to some example embodiments.

Referring to FIG. 15A, in some example embodiments, the semiconductor substrate 100 including the pixel electrodes 120, the wiring structure 130, the photodiodes PD, the pixel isolators 110, and the device isolators 107 is provided. According to some example embodiments, the semiconductor substrate 100 is prepared, and some components of the pixels PX are formed on the second surface 100b of the semiconductor substrate 100. In this operation, the pixel electrodes 120, the insulating layer 140, and the wiring structure 130 are formed on the second surface 100b of the semiconductor substrate 100, and the pixel isolators 110 and the device isolators 107 are formed in the direction from the second surface 100b toward the first surface 100a of the semiconductor substrate 100.

The pixel isolators 110 may be formed by forming deep trenches recessed from the first surface 100a and filling the deep trenches with an insulating material or a conductive material. When the deep trenches are filled with a conductive material, an insulating liner may be interposed between the conductive material and the semiconductor substrate 100. Thereafter, portions of the semiconductor substrate 100 on the first surface 100a side may be removed through chemical mechanical polishing until the pixel isolators 110 penetrate the opposite sides of the semiconductor substrate 100. The device isolators 107 may be formed by forming shallow trenches and filling the shallow trenches with an insulating material.

Referring to FIG. 15B, in some example embodiments, to form the optical path changing member LM in the central portion of the pixel group PXG, a depression is formed by etching a portion of the first surface 100a of the semiconductor substrate 100. Accordingly, the wall surface of the depression is the curved surface that forms the optical path changing member LM. At this time, the optical path changing member LM is formed to overlap the regions where the pixel isolators 110 are formed.

Referring to FIG. 15C, in some example embodiments, the depression formed by etching and removing a portion of the semiconductor substrate 100 may be filled with an insulating material.

Referring to FIG. 15D, in some example embodiments, a grid layer 160 is formed on the first surface 100a of the semiconductor substrate 100 having the insulating material therein.

Referring to FIG. 15E, in some example embodiments, the color filters CF are formed on the semiconductor substrate 100 having the grid layer 160 formed thereon. The color filters CF may be formed to correspond to the respective pixel groups PXG.

Referring to FIG. 15F, in some example embodiments, the micro lenses ML are formed on the semiconductor substrate 100 having the color filters CF formed thereon. The micro lenses ML may be manufactured by forming the planarization layers to flatten the upper surface on which the color filters CF are formed and then forming the micro lens parts on the planarization layers. For example, the planarization layers and the micro lens parts may be formed of different materials. However, in some example embodiments, the planarization layers and the micro lens parts may be formed of the same material. In some example embodiments, the planarization layers and the micro lens parts may be integrally formed with each other.

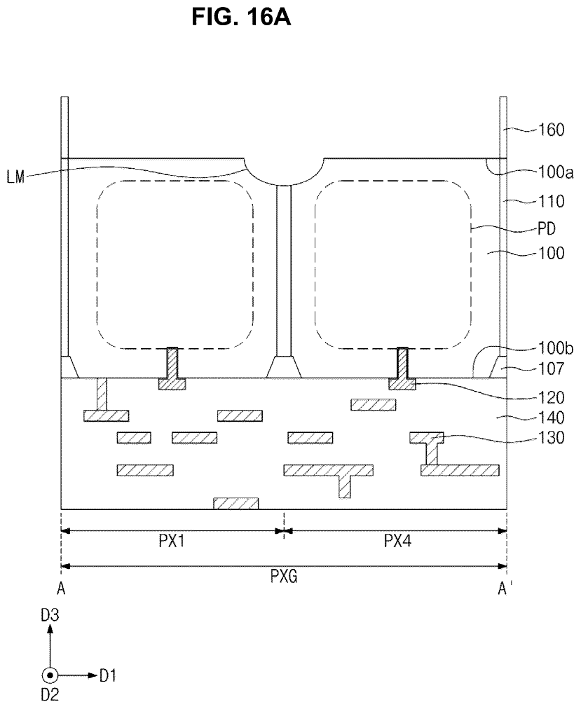

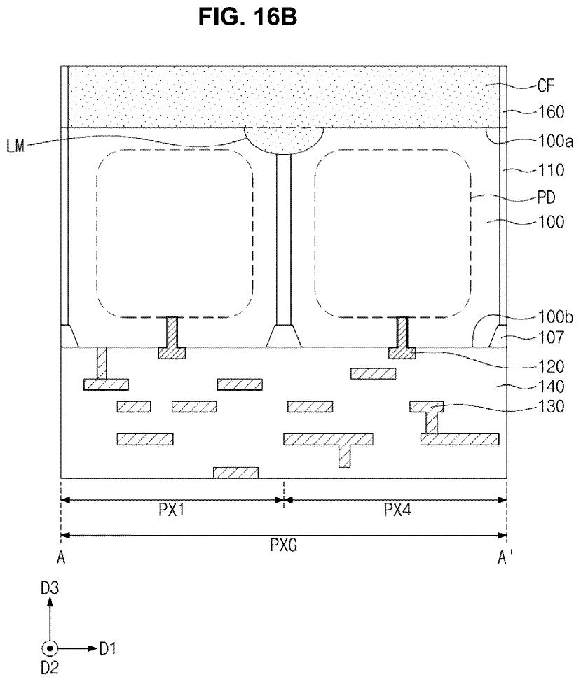

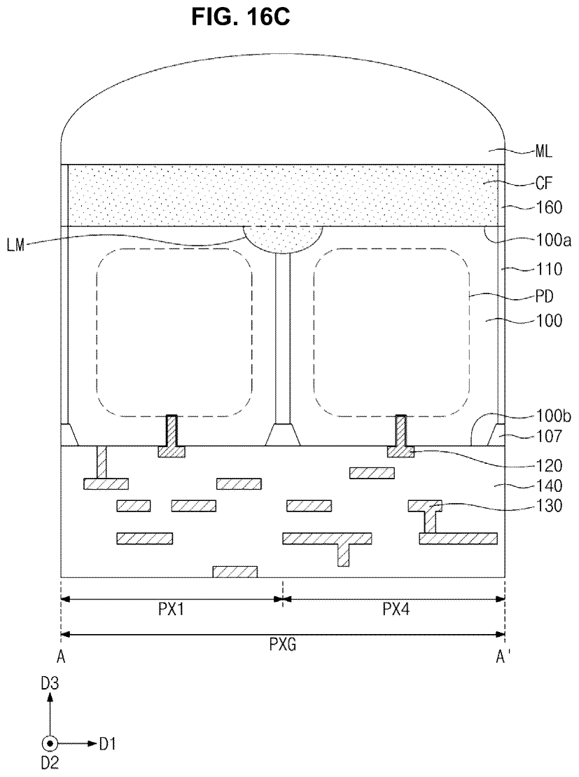

FIGS. 16A to 16C are sectional views sequentially illustrating a method for manufacturing the image sensor illustrated in FIG. 8 according to some example embodiments, and processes substantially the same as those in the above-described example embodiments are omitted.

According to some example embodiments, to manufacture the image sensor illustrated in FIG. 8, the semiconductor substrate 100 including the pixel electrodes 120, the wiring structure 130, the photodiodes PD, the pixel isolators 110, and the device isolators 107 are formed as illustrated in, for example, FIG. 15A, and the depression is formed by etching a portion of the first surface 100a of the semiconductor substrate 100 to form the optical path changing member LM in the central portion of the pixel group PXG as illustrated in, for example, FIG. 15B. The depression may be formed in various shapes and sizes by etching the semiconductor substrate 100 to reflect the shape or size of the optical path changing member LM to be formed.

Referring to FIG. 16A, in some example embodiments, the grid layer 160 is formed on the first surface 100a of the semiconductor substrate 100 having the insulating material therein.

Referring to FIG. 16B, in some example embodiments, the color filters CF are formed on the semiconductor substrate 100 having the grid layer 160 formed thereon. The color filters CF may be formed to correspond to the respective pixel groups PXG.

Referring to FIG. 16C, in some example embodiments, the micro lenses ML are formed on the semiconductor substrate 100 having the color filters CF formed thereon. The micro lenses ML may be manufactured by forming the planarization layers to flatten the upper surface on which the color filters CF are formed and then forming the micro lens parts on the planarization layers.

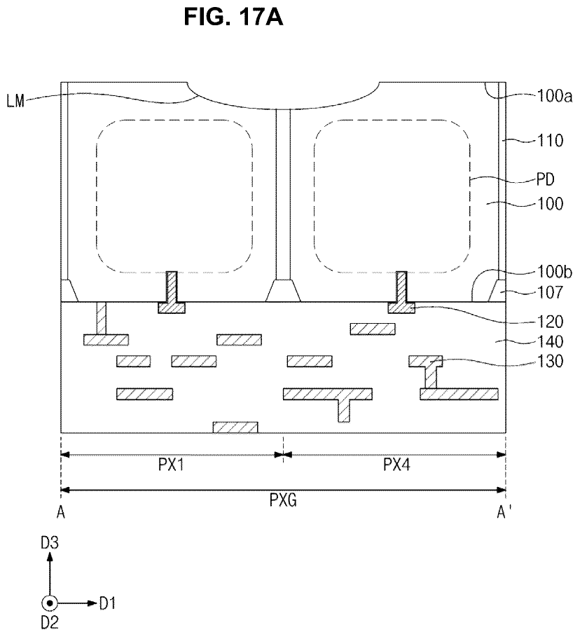

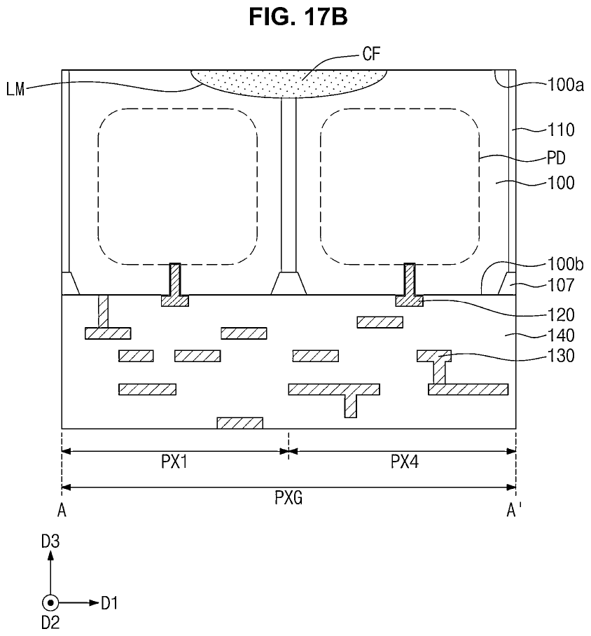

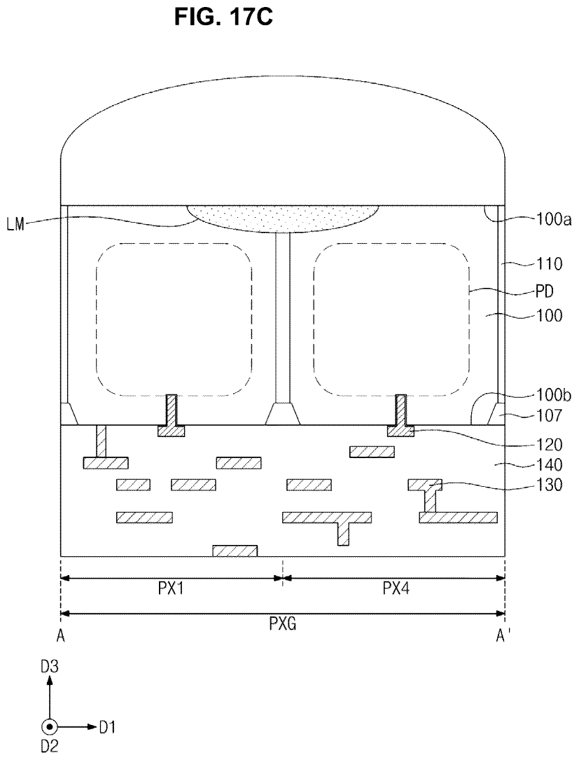

FIGS. 17A to 17C are sectional views sequentially illustrating a method for manufacturing the image sensor illustrated in FIG. 9 according to some example embodiments, and processes substantially the same as those in the above-described example embodiments are omitted.

According to some example embodiments, to manufacture the image sensor illustrated in FIG. 9, first, the semiconductor substrate 100 including the pixel electrodes 120, the wiring structure 130, the photodiodes PD, the pixel isolators 110, and the device isolators are formed as illustrated in, for example, FIG. 15A.

Next, as illustrated in, for example, FIG. 17A, to form the optical path changing member LM in the central portion of the pixel group PXG, the depression is formed by etching a portion of the first surface 100a of the semiconductor substrate 100. The depression may be formed in various shapes and sizes by etching the semiconductor substrate 100 to reflect the shape or size of the optical path changing member LM to be formed.

Referring to FIG. 17B, in some example embodiments the depression formed by etching and removing a portion of the semiconductor substrate 100 may be filled with one of the color filters CF.

Referring to FIG. 17C, in some example embodiments, the micro lens ML is formed on the semiconductor substrate 100 having the color filter CF that fills the depression.

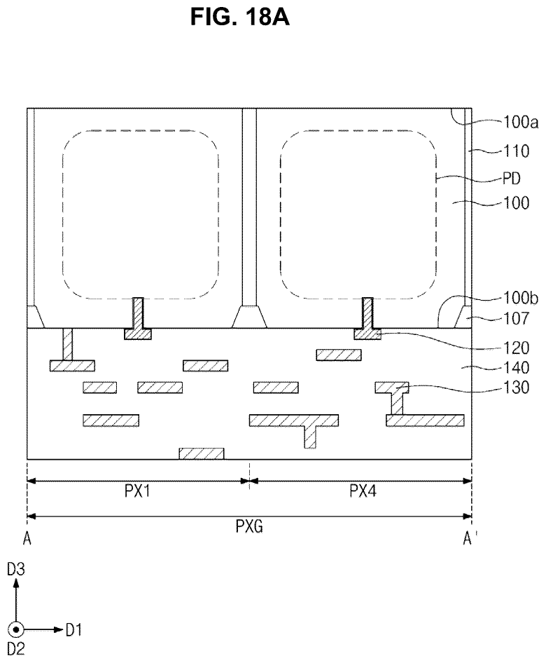

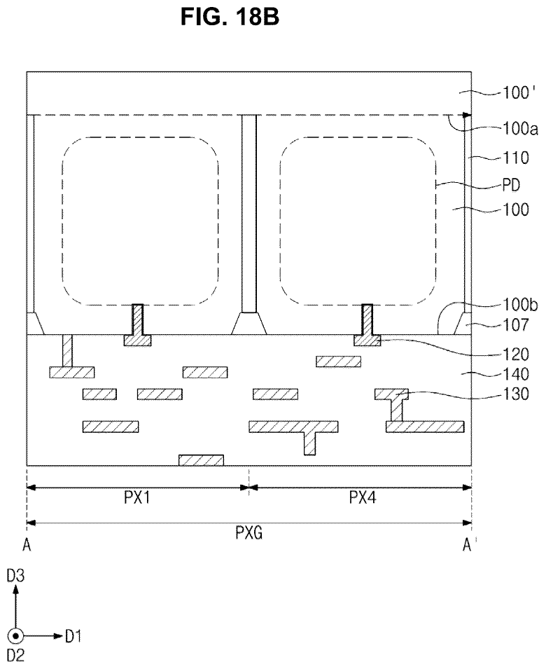

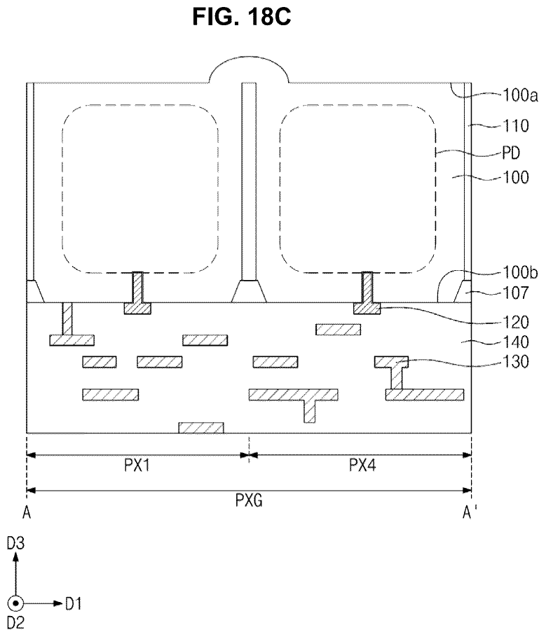

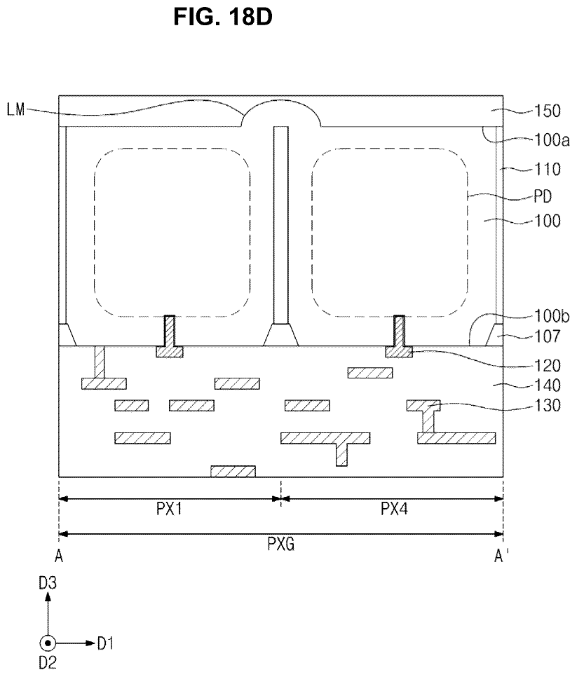

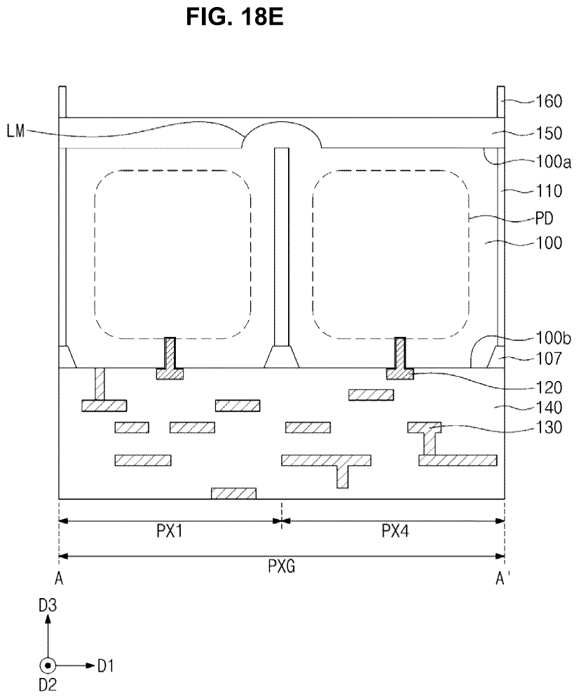

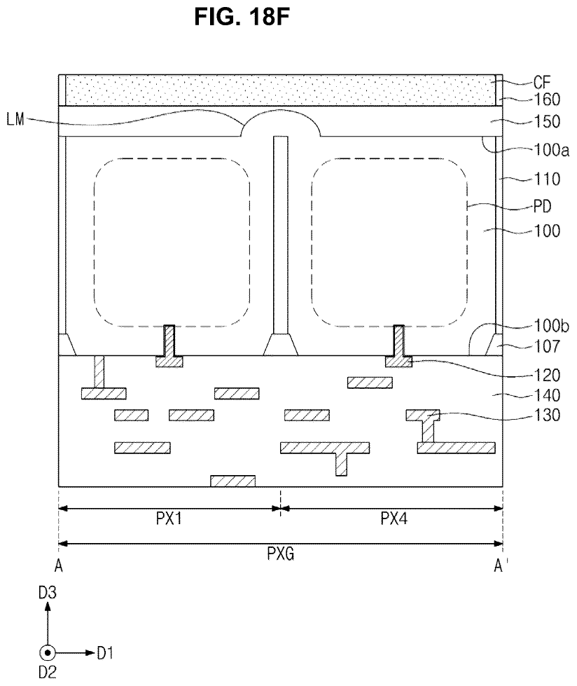

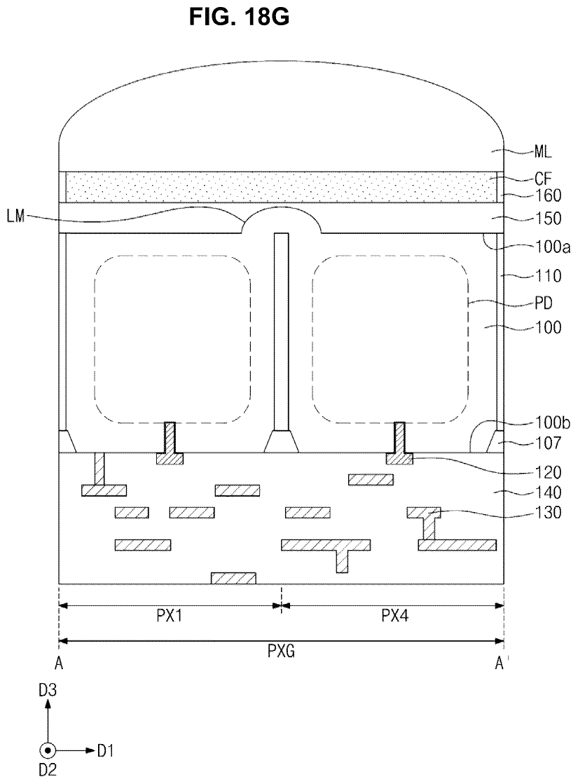

FIGS. 18A to 18G are sectional views sequentially illustrating a method for manufacturing the image sensor illustrated in FIG. 10 according to some example embodiments.

Referring to FIG. 18A, in some example embodiments, first, the semiconductor substrate 100 including the pixel electrodes 120, the wiring structure 130, the photodiodes PD, the pixel isolators 110, and the device isolators 107 are formed.

Referring to FIG. 18B, in some example embodiments, an additional layer 100′ formed of the same material as that of the semiconductor substrate 100 is formed on the semiconductor substrate 100. For example, the additional layer 100′ corresponds to a layer in which the optical path changing member LM is to be formed through patterning.

Referring to FIG. 18C, in some example embodiments, the optical path changing member LM is formed by making the additional layer 100′ subject to patterning. The optical path changing member LM is manufactured by forming the protrusion protruding upward from the semiconductor substrate 100 in the third direction D3 by etching the upper surface of the additional layer 100′ on the semiconductor substrate 100.

Referring to FIG. 18D, in some example embodiments, the interlayer film 150 covering the optical path changing member LM is formed on the semiconductor substrate 100 having the optical path changing member LM formed thereon.

Referring to FIG. 18E, in some example embodiments, the grid layer 160 is formed on the first surface 100a of the semiconductor substrate 100 having the interlayer film 150 formed thereon.

Referring to FIG. 18F, in some example embodiments, the color filters CF are formed on the semiconductor substrate 100 having the grid layer 160 formed thereon. The color filters CF may be formed to correspond to the respective pixel groups PXG.

Referring to FIG. 18G, in some example embodiments, the micro lenses ML are formed on the semiconductor substrate 100 having the color filters CF formed thereon. The micro lenses ML may be manufactured by forming the planarization layers to flatten the upper surface on which the color filters CF are formed and then forming the micro lens parts on the planarization layers.

According to some example embodiments of the present inventive concepts, the image sensor may be manufactured by a simple method as described above.

The optical path changing member LM according to some example embodiments of the present inventive concepts may be applied to various pixel arrays PA different from those in the above-described example embodiments.

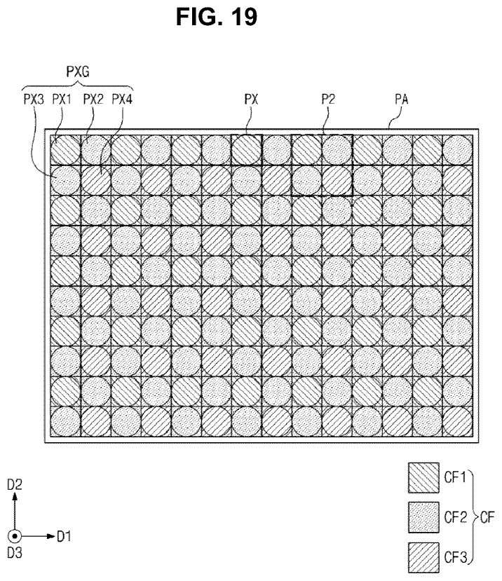

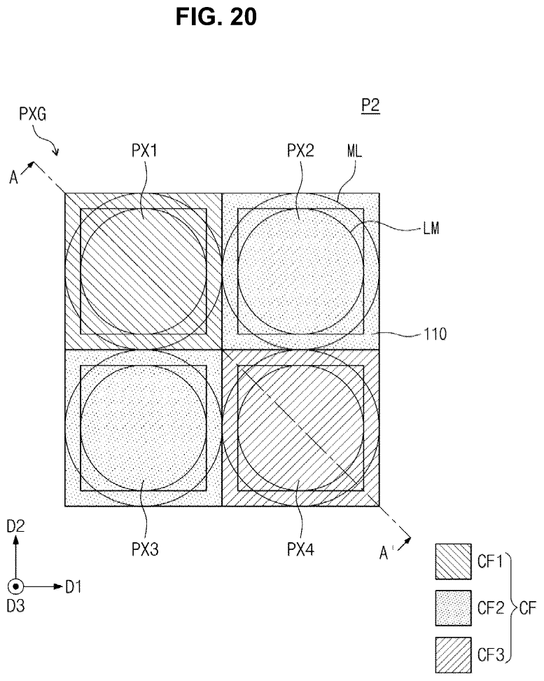

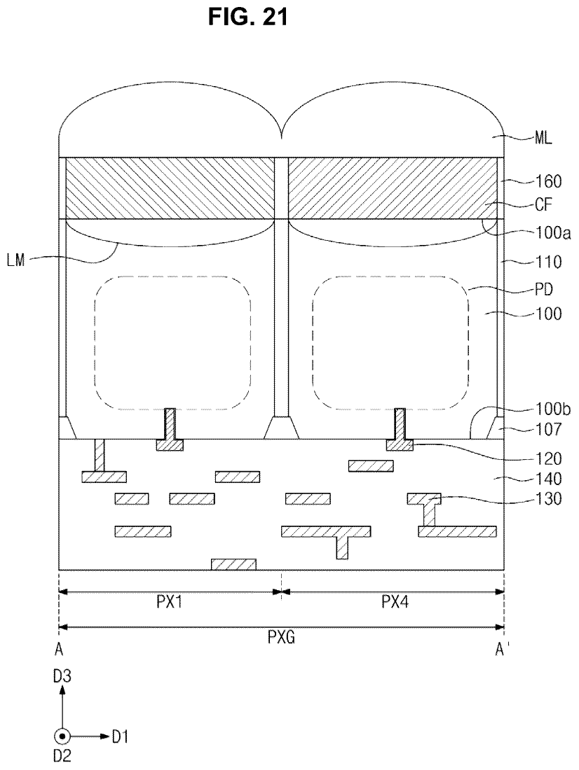

FIG. 19 is a view illustrating a pixel array PA including a plurality of pixel groups PXG according to some example embodiments, FIG. 20 is a plan view illustrating portion P2 in FIG. 19 according to some example embodiments, and FIG. 21 is a sectional view taken along line A-A′ of FIG. 20 according to some example embodiments.

Referring to FIGS. 19 to 21, an image sensor according to some example embodiments of the present inventive concepts includes the pixel array PA including pixels PX. The plurality of pixel groups PXG may be provided in the pixel array PA. Each of the pixel groups PXG may include first to fourth pixels PX1, PX2, PX3, and PX4. The pixel group PXG may include the first to fourth pixels PX1, PX2, PX3, and PX4 arranged in a 2×2 matrix form. In some example embodiments, the row direction may be the first direction D1, and the column direction may be the second direction D2. The first and second pixels PX1 and PX2 are sequentially disposed in the first direction D1, and the third and fourth pixels PX3 and PX4 are sequentially disposed in the first direction D1. The first and second pixels PX1 and PX2 form the first row, and the third and fourth pixels PX3 and PX4 form the second row.

Each of the first to fourth pixels PX1, PX2, PX3, and PX4 may include one photodiode PD, and the colors of the first to fourth pixels PX1, PX2, PX3, and PX4 may be implemented by color filters CF corresponding to the respective pixels PX. First to third color filters CF1, CF2, and CF3 may correspond to the respective pixels PX. According to some example embodiments of the present inventive concepts, the first to third color filters CF1, CF2, and CF3 may represent a blue color, a green color, and a red color, respectively. Blue may correspond to the first pixel PX1, green may correspond to the second pixel PX2, green may correspond to the third pixel PX3, and red may correspond to the fourth pixel PX4.

According to some example embodiments, for example, as illustrated in FIG. 21, an optical path changing member LM is provided between a semiconductor substrate 100 and the color filter CF. The optical path changing member LM may have a curved surface that is concave or convex in a direction from a first surface 100a toward a second surface 100b of the semiconductor substrate 100. For example, as illustrated in FIG. 21, the optical path changing member LM may have a depression recessed in the direction from the first surface 100a toward the second surface 100b. The depression may be filled with a material different from that of the semiconductor substrate 100 so as to have a refractive index different from the refractive index of the semiconductor substrate 100. For example, the depression may be filled with an insulating material different from the material of the semiconductor substrate 100. The insulating material may include not only silicon oxide, silicon nitride, or silicon oxy nitride but also various inorganic materials and various organic materials such as polyvinyl alcohol. The refractive index of light passing through the optical path changing member LM may be determined depending on the selection of the insulating material.

In some example embodiments, for example, as illustrated in FIGS. 20 and 21, the optical path changing member LM, when viewed from above the plane, may cover the entire region of the first surface 100a of the semiconductor substrate 100 other than a pixel isolator 110. However, without being limited thereto, the optical path changing member LM, according to some example embodiments, may cover only a portion of the first surface 100a. The area or shape of the optical path changing member LM may be differently set to correspond to the shape of a corresponding micro lens ML depending on the amount, incidence angle, and color of light incident to the semiconductor substrate 100.

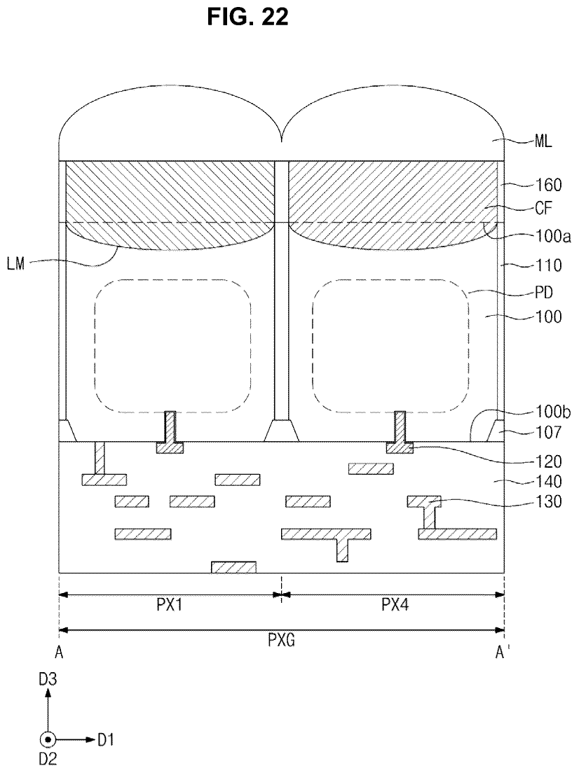

FIGS. 22 to 25 illustrate image sensors according to some example embodiments, where FIGS. 22 to 25 are sectional views corresponding to line A-A′ of FIG. 20.

Referring to FIG. 22, a depression of an optical path changing member LM according to some example embodiments of the present inventive concepts may be filled with one color filter CF among color filters CF.

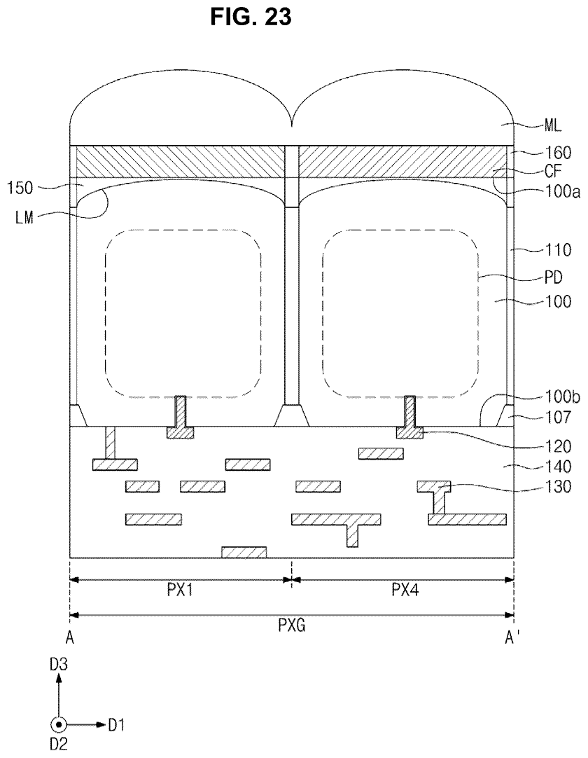

Referring to FIG. 23, in some example embodiments, an optical path changing member LM may have a protrusion that protrudes in a direction opposite to a direction from a first surface 100a toward a second surface 100b, for example, in the third direction D3. In some example embodiments, the inside of the protrusion may be filled with the same material as that of a semiconductor substrate 100. For example, likewise to the semiconductor substrate 100, the protrusion may be formed of a semiconductor material, for example, a Group IV semiconductor. The Group IV semiconductor may include silicon, germanium, or silicon-germanium, and the protrusion may be integrally formed with the semiconductor substrate 100. In some example embodiments, an interlayer film 150 covering the protrusion may be provided between the protrusion and color filters CF.

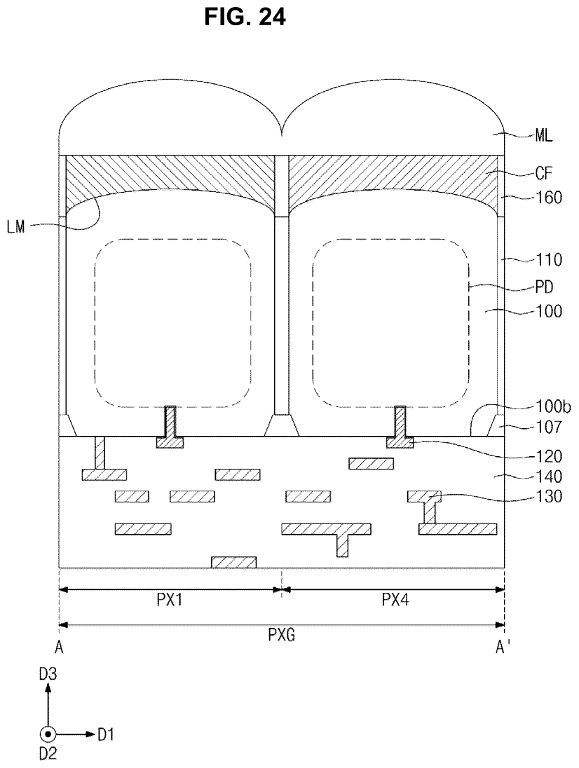

Referring to FIG. 24, in some example embodiments, an optical path changing member LM may have a curved surface having a shape protruding in the third direction D3 similarly to that illustrated in, for example, FIG. 10, and the inside of the protrusion may be filled with the same material as that of a semiconductor substrate 100. However, unlike some example embodiments, for example, as illustrated in FIG. 19, the interlayer film 150 may be omitted, and color filters CF may be provided on the semiconductor substrate 100.

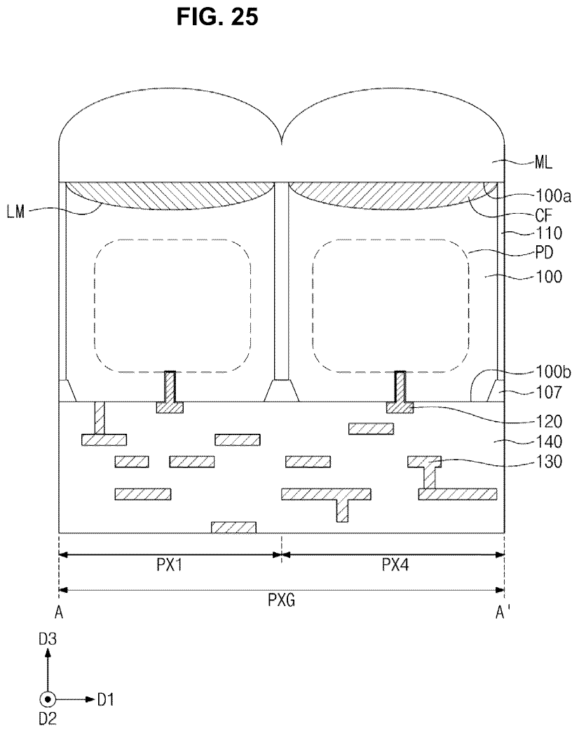

Referring to FIG. 25, in the image sensor according to some example embodiments, a color filter CF may not be formed as a separate layer, but may be formed only within a depression of an optical path changing member LM using the optical path changing member LM. For example, among color filters CF, one color filter CF corresponding to a corresponding pixel PX may fill only the depression, and a micro lens ML may be directly disposed on the depression.

The optical path changing member LM according to some example embodiments of the present inventive concepts may be applied to various pixel arrays different from that in the above-described example embodiments.

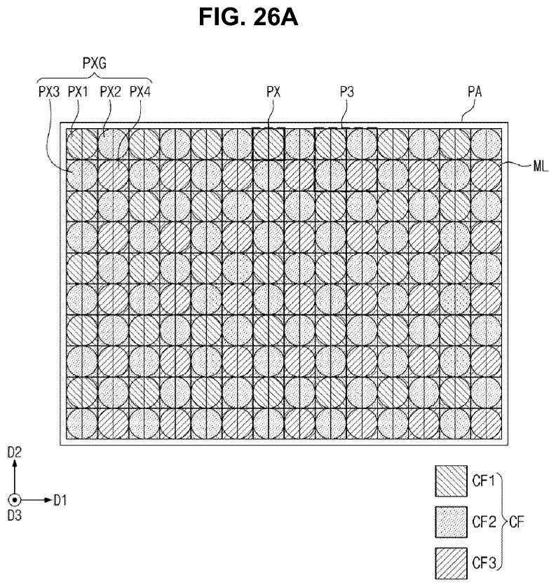

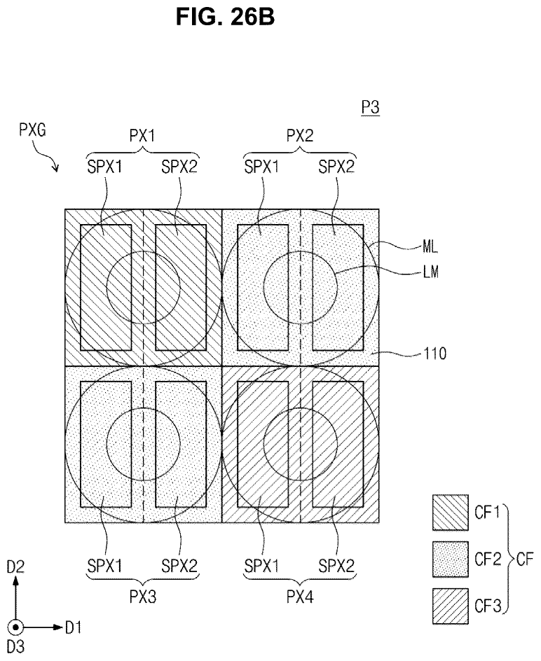

FIG. 26A illustrates a pixel array PA according to some example embodiments, and FIG. 26B is a plan view illustrating portion P3 in FIG. 26A according to some example embodiments.

Referring to FIGS. 26A and 26B, an image sensor according to some example embodiments of the present inventive concepts includes the pixel array PA including pixels PX. A plurality of pixel groups PXG may be provided in the pixel array PA. Each of the pixel groups PXG may include first to fourth pixels PX1, PX2, PX3, and PX4. The pixel group PXG may include the first to fourth pixels PX1, PX2, PX3, and PX4 arranged in a 2×2 matrix form. In some example embodiments, micro lenses ML are provided for the first to fourth pixels PX1, PX2, PX3, and PX4, respectively. For example, the first to fourth pixels PX1, PX2, PX3, and PX4 do not share the same micro lens ML.

According to some example embodiments, as illustrated in, for example, FIG. 26B, each of the pixels PX may include a first sub-pixel SPX1 and a second sub-pixel SPX2 that share one micro lens ML. The image sensor according to some example embodiments may obtain an image signal. In some example embodiments, the image sensor may perform auto focusing since the first sub-pixel SPX1 and the second sub-pixel SPX2 are capable of sensing a phase difference of light incident through the one micro lens ML.

In some example embodiments, optical path changing members LM are provided in the first to fourth pixels PX1, PX2, PX3, and PX4 in a one-to-one manner, and each of the optical path changing members LM is provided between the two sub-pixels SPX1 and SPX2 adjacent to each other. In some example embodiments, a pixel isolator 110 may have a shape extending only in one direction (e.g., the second direction as illustrated in FIG. 26B) rather than a cross shape. The pixel isolator 110 may be provided between the two sub-pixels SPX1 and SPX2 adjacent to each other, and the optical path changing member LM may refract light to allow the light to travel toward the two sub-pixels SPX1 and SPX2 without travelling toward the pixel isolator 110 between the two sub-pixels SPX1 and SPX2.

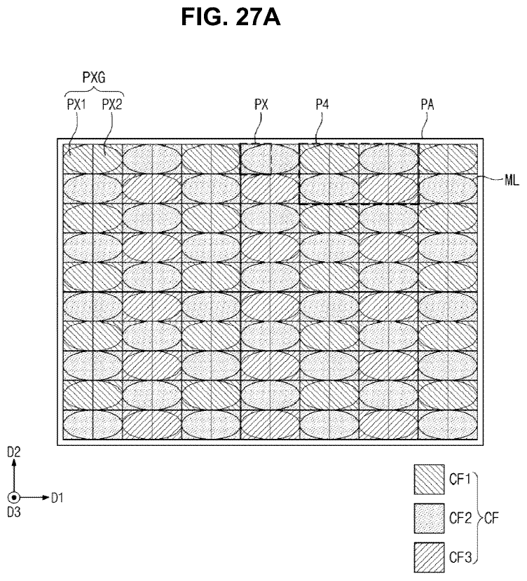

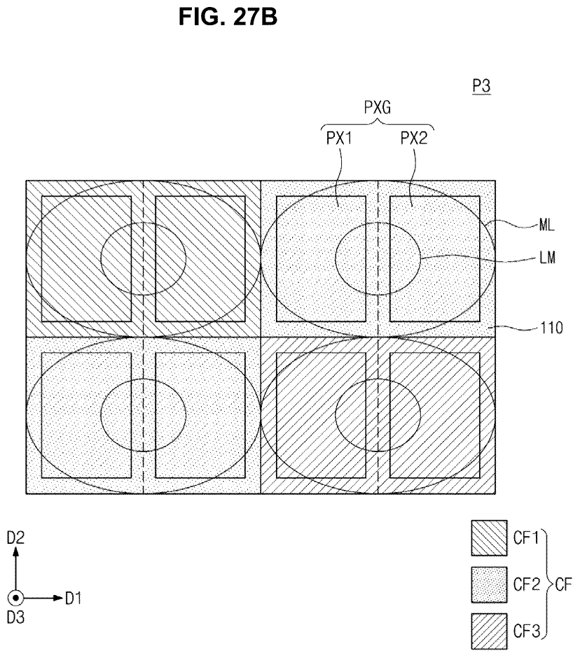

FIG. 27A illustrates a pixel array PA according to some example embodiments, and FIG. 27B is a plan view illustrating portion P4 in FIG. 27A according to some example embodiments.

Referring to FIGS. 27A and 27B, an image sensor according to some example embodiments of the present inventive concepts includes the pixel array PA including pixels PX. A plurality of pixel groups PXG may be provided in the pixel array PA. Each of the pixel groups PXG may include two pixels, for example, first and second pixels PX1 and PX2. In some example embodiments, one micro lens ML is provided for the first and second pixels PX1 and PX2. Accordingly, the first and second pixels PX1 and PX2 share the one micro lens ML.

The image sensor according to some example embodiments may obtain an image signal from the two pixels PX1 and PX2 adjacent to each other. In some example embodiments, the image sensor may perform auto focusing since the first pixel PX1 and the second pixel PX2 are capable of sensing a phase difference of light incident through the one micro lens ML.

In some example embodiments, depending on the arrangement of the first pixel PX1 and the second pixel PX2, the micro lens ML may not have a circular shape. For example, the micro lens ML may have an oval shape as illustrated in FIGS. 27A and 27B. In some example embodiments, an optical path changing member LM may have various shapes, for example, an oval shape depending on the shape of the micro lens ML and the position of a focus due to this.

In the above-described example embodiments, for convenience of description, it has been described that the pixels PX and/or the pixel groups PXG having the same shape are provided in the pixel arrays PA. However, arrangements of the pixel arrays PA according to some example embodiments are not limited thereto.

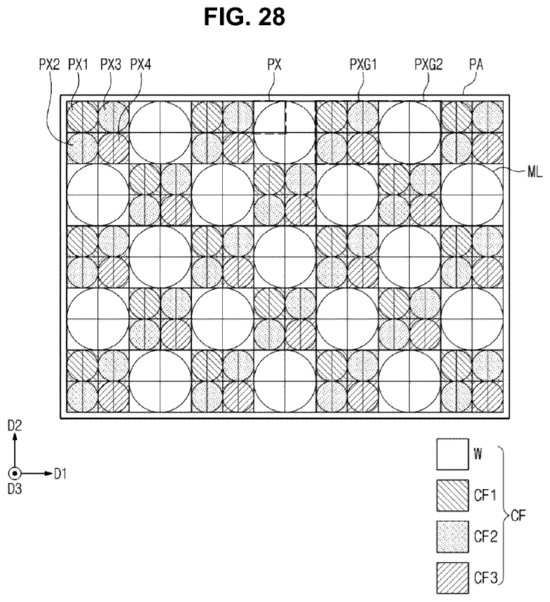

FIG. 28 illustrates a pixel array PA according to some example embodiments.

Referring to FIG. 28, in some example embodiments, the pixel array PA may include two or more types of pixel groups PXG having different forms. For example, the pixel array PA may include first and second pixel groups PXG1 and PXG2 different from each other. The first pixel group PXG1 may include first to fourth pixels PX1, PX2, PX3, and PX4, and micro lenses ML may be provided for the first to fourth pixels PX1, PX2, PX3, and PX4, respectively. The second pixel group PXG2 may include first to fourth pixels PX1, PX2, PX3, and PX4, and the first to fourth pixels PX1, PX2, PX3, and PX4 may share one micro lens ML. In some example embodiments, each of the pixels PX of the first pixel group PXG1 may include a first sub-pixel SPX1 and a second sub-pixel SPX2.

In some example embodiments, the pixel array PA may further include another color filter CF, for example, a color filter W representing white in addition to first to third color filters CF1, CF2, and CF3. One color filter CF among the first to third color filters CF1, CF2, and CF3 may be provided for each of the pixels PX of the first pixel group PXG1, and the color filter W representing white may be provided for each of the pixels PX of the second pixel group PXG2.

In the pixel array PA having the different pixel groups PXG, optical path changing members LM may be provided in various forms depending on the pixels PX and/or the pixel groups PXG.

In the above-described example embodiments, for convenience of description, it has been described that the pixels PX and/or the pixel groups PXG have a quadrangular shape. However, the shapes of the pixels PX and/or the pixel groups PXG according to some example embodiments are not limited thereto. For example, according to some example embodiments of the present inventive concepts, the shapes of the separate pixels PX and/or the separate pixel groups PXG may be changed in various different ways. For example, in some example embodiments, the pixels PX and/or the pixel groups PXG may have a hexagonal honeycomb shape. Alternatively, in some example embodiments some of the pixels PX and/or the pixel groups PXG may have a quadrangular shape, and the others may have an octagonal shape.

Furthermore, in the above-described example embodiments, the components may be combined in various forms as long as the components are not incompatible with one another. For example, although all of the pixels PX are illustrated as having the first and second sub-pixels SPX1 and SPX2 in the above-described example embodiments, only some of the pixels PX in the pixel array PA may have the first and second sub-pixels SPX1 and SPX2, and the other pixels may have only one pixel without the sub-pixels. Furthermore, although the 2×2 pixels are illustrated as forming one pixel group PXG in the above-described example embodiments, the present inventive concepts are not limited thereto, and 3×3 pixels may form one pixel group PXG, or various other combinations may be possible. For example, some of the pixel groups PXG may each have 2×2 pixels, other pixel groups PXG may each have 1×2 pixels, and the other pixel groups PXG may each have 2×1 pixels.

According to some example embodiments of the present inventive concepts, image sensors with improved light receiving efficiency are provided. According to some example embodiments of the present inventive concepts, image sensors in which a crosstalk phenomenon caused by plain light is improved are provided.

While the present inventive concepts have been shown and described with reference to some example embodiments thereof, it will be apparent to those of ordinary skill in the art that various changes and modifications in form and details may be made thereto without departing from the spirit and scope of the present inventive concepts as set forth in the following claims.

Accordingly, the scope of the present inventive concepts should not be determined by the above-described example embodiments and should be determined by the accompanying claims and the equivalents thereof.

What is claimed is:

1. An image sensor, comprising:
a plurality of pixels arranged in a matrix form;
photodiodes for respective pixels of the plurality of pixels, the photodiodes within a semiconductor substrate having a first surface to which light is incident and a second surface facing away from the first surface;
micro lenses over the first surface of the semiconductor substrate and configured to concentrate the light;
color filters between the semiconductor substrate and the micro lenses; and
an optical path changing member configured to change a path of at least a portion of the light when the light travels toward the photodiodes through the micro lenses,
wherein the optical path changing member has a curved surface being concave or convex on the first surface of the semiconductor substrate.

2. The image sensor of claim 1, wherein at least two pixels among the plurality of pixels share one micro lens among the micro lenses, and the optical path changing member, when viewed from above a plane, is at a center of the at least two pixels.

3. The image sensor of claim 2, wherein the optical path changing member has the curved surface being concave or convex in a direction from the first surface of the semiconductor substrate toward the second surface of the semiconductor substrate.

4. The image sensor of claim 3, wherein the optical path changing member has a depression recessed in the direction from the first surface of the semiconductor substrate toward the second surface of the semiconductor substrate.

5. The image sensor of claim 4, wherein the depression includes an insulating material.

6. The image sensor of claim 5, wherein the depression includes one of the color filters.

7. The image sensor of claim 6, wherein the one of the color filters is in only the depression.

8. The image sensor of claim 3, wherein the optical path changing member has a protrusion protruding in a direction opposite to the direction from the first surface of the semiconductor substrate toward the second surface of the semiconductor substrate.

9. The image sensor of claim 8, wherein the protrusion includes a same material as the semiconductor substrate.

10. The image sensor of claim 9, further comprising:
an interlayer film between the protrusion and the color filters.

11. The image sensor of claim 2, further comprising:
a pixel isolator within the semiconductor substrate and dividing the plurality of pixels from each other,
wherein the optical path changing member overlaps the pixel isolator when viewed from above the plane.

12. The image sensor of claim 11, wherein when viewed from above the plane, a portion of the pixel isolator is removed, and the optical path changing member is in a region from which the portion of the pixel isolator is removed.

13. The image sensor of claim 2, wherein the plurality of pixels include a plurality of pixel groups, each of the plurality of pixel groups including first to fourth pixels arranged in a 2×2 matrix form.

14. The image sensor of claim 13, wherein the plurality of pixel groups include first to fourth pixel groups arranged in a 2×2 matrix, and the first to fourth pixel groups include a blue filter, a first green filter, a second green filter, and a red filter, respectively.

15. The image sensor of claim 13, wherein the plurality of pixel groups include first to fourth pixel groups arranged in a 2×1 matrix, and the first to fourth pixel groups include a blue filter, a first green filter, a second green filter, and a red filter, respectively.

16. The image sensor of claim 1, wherein the optical path changing member overlaps focuses of the micro lenses when viewed from above a plane.

17. The image sensor of claim 1, wherein materials on opposite sides of the curved surface with respect to the curved surface of the optical path changing member have different refractive indexes.

18. An image sensor, comprising:
a plurality of pixel groups, each of which has one color among first to third colors, wherein each of the plurality of pixel groups includes first to fourth pixels arranged in a 2×2 matrix form;
photodiodes for the first to fourth pixels, the photodiodes within a semiconductor substrate having a first surface to which light is incident and a second surface facing away from the first surface;
micro lenses over the first surface of the semiconductor substrate corresponding to the first to fourth pixels and configured to concentrate the light;
a color filter between the semiconductor substrate and the micro lenses; and
an optical path changing member configured to change a path of at least a portion of the light when the light travels toward the photodiodes through the micro lenses,
wherein the optical path changing member has a curved surface extending from the first surface of the semiconductor substrate, the curved surface being concave or convex in a direction toward the second surface of the semiconductor substrate.

19. The image sensor of claim 18, wherein the optical path changing member overlaps focuses of the micro lenses when viewed from above a plane, and materials on opposite sides of the curved surface with respect to the curved surface of the optical path changing member have different refractive indexes.

20. A method for manufacturing an image sensor, the method comprising:
providing a semiconductor substrate having a first surface and a second surface facing away from the first surface, the semiconductor substrate including photodiodes and pixel isolators formed therein;
forming an optical path changing member on a region of the first surface of the semiconductor substrate overlapping the pixel isolators when viewed from above a plane;
forming a color filter on the semiconductor substrate having the optical path changing member formed thereon; and
forming a micro lens on the semiconductor substrate having the color filter formed thereon,
wherein the optical path changing member has a curved surface extending from the first surface of the semiconductor substrate, the curved surface being concave or convex in a direction toward the second surface of the semiconductor substrate.
